(19) United States
(12) Patent Application Publication
(10) Pub. No.: US 2015/0371999 A1
(43) Pub. Date: Dec. 24, 2015

(54) SEMICONDUCTOR DEVICE, SEMICONDUCTOR STORAGE DEVICE AND METHOD OF MANUFACTURING THE SEMICONDUCTOR DEVICE

(71) Applicant: KABUSHIKI KAISHA TOSHIBA, Tokyo (JP)

(72) Inventor: Takashi KURUSU, Yamato Kanagawa (JP)

(73) Assignee: KABUSHIKI KAISHA TOSHIBA, Tokyo (JP)

(21) Appl. No.: 14/483,034

(22) Filed: Sep. 10, 2014

Related U.S. Application Data
(60) Provisional application No. 62/013,964, filed on Jun. 18, 2014.

(51) Int. Cl. H01L 27/115; H01L 23/532; H01L 29/792; H01L 29/417; H01L 21/02; H01L 21/768; H01L 21/66; H01L 23/528; H01L 29/788

(52) U.S. Cl. CPC H01L 27/11573; H01L 23/528; H01L 23/53228; H01L 23/53214; H01L 23/53257; H01L 29/7926; H01L 29/7889; H01L 21/02175; H01L 21/76838; H01L 22/26; H01L 21/76892; H01L 27/11565; H01L 27/1157; H01L 27/11519; H01L 27/11524; H01L 27/11529; H01L 23/53242; H01L 23/5329; H01L 29/41725

(57) ABSTRACT

According to an embodiment, a semiconductor device includes a plurality of wires provided on an insulating layer. Each of the wires includes one or more metal crystal grains. An average width of each of the wires and an average interval between the wires adjacent to each other are nearly equal to or less than a mean free path of free electrons in a bulk crystal of the metal. A specific crystal orientation in which size effect of electrical resistivity weakens due to anisotropy of Fermi velocity in the metal is substantially parallel to a current direction in at least a part of the crystal grains in each of the wires.

### CROSS REFERENCE TO RELATED APPLICATIONS

This application is based upon and claims the benefit of priority from the prior U.S. Provisional Patent Application No. 62/013,964, filed on Jun. 18, 2014, the entire contents of which are incorporated herein by reference.

### FIELD

Embodiments described herein relate generally to a semiconductor device, a semiconductor storage device and a method of manufacturing the semiconductor device.

### BACKGROUND

The resistance of a metal wire in a semiconductor integrated circuit increases as the wire is miniaturized. This reduces the circuit performance.

### BRIEF DESCRIPTION OF THE DRAWINGS

FIG. 1 is a perspective view of a part of a semiconductor device according to a first embodiment.

FIG. 2 is a top view of a part of the semiconductor device in the first embodiment.

FIGS. 3(a) to 3(f) are cross-sectional views describing a process for manufacturing the semiconductor device in FIG. 1.

FIG. 4 is a view of the simulation result of the dependence of the resistivity of a single crystal Cu{100} wire on the crystal orientation.

FIG. 5 is a perspective view of a part of a semiconductor device according to a second embodiment.

FIG. 6 is a view of the simulation result of the dependence of the resistivity of a single crystal Cu{110} wire on the crystal orientation.

FIG. 7 is a view of the simulation result of the dependence of the resistivity of a single crystal Ag{100} wire on the crystal orientation.

FIG. 8 is a view of the simulation result of the dependence of the resistivity of a single crystal Au{100} wire on the crystal orientation.

FIG. 9 is a view of the simulation result of the dependence of the resistivity of a single crystal Ag{110} wire on the crystal orientation.

FIG. 10 is a view of the simulation result of the dependence of the resistivity of a single crystal Au{110} wire on the crystal orientation.

FIG. 11 is a perspective view of a part of a semiconductor device according to a fourth embodiment.

FIG. 12 is a view of the simulation result of the dependence of the resistivity of a single crystal Al{100} wire on the crystal orientation.

FIG. 13 is a perspective view of a part of a semiconductor device according to a fifth embodiment.

FIG. 14 is a view of the simulation result of the dependence of the resistivity of a single crystal Al{110} wire on the crystal orientation.

FIG. 15 is a perspective view of a part of a semiconductor device according to a sixth embodiment.

FIG. 16 is a view of the simulation result of the dependence of the resistivity of a single crystal Mo{110} wire on the crystal orientation.

FIG. 17 is a perspective view of a part of a semiconductor device according to a seventh embodiment.

FIG. 18 is a view of the simulation result of the dependence of the resistivity of a single crystal Mo{100} wire on the crystal orientation.

FIG. 19 is a schematic plan view of the structure of a semiconductor storage device according to an eighth embodiment.

FIG. 20 is a cross-sectional view taken along line A-A in FIG. 19.

FIG. 21 is a schematic plan view of the structure of a semiconductor storage device according to a ninth embodiment.

FIG. 22 is a perspective view of a region R1 in FIG. 21.

FIG. 23 is a schematic plan view of the structure of a semiconductor storage device according to a tenth Embodiment.

FIG. 24 is a perspective view of a region R2 in FIG. 23.

FIG. 25 is a perspective view of a part of a semiconductor device in a comparative example.

FIG. 26 is a view showing loci of the electrons in a device.

FIG. 27 is a view of the comparison of electrical resistivity between the simulation results obtained by the Monte Carlo simulator and the actual measured values.

FIG. 28 is a view of the simulation result of the variation of the resistivity when the crystal orientation of the W crystal is rotated from a [100] direction to a [011] direction on a {110} surface.

### DETAILED DESCRIPTION

According to an embodiment, a semiconductor device includes a plurality of wires provided on an insulating layer. Each of the wires includes one or more metal crystal grains. An average width of each of the wires and an average interval between the wires adjacent to each other are nearly equal to or less than a mean free path of free electrons in a bulk crystal of the metal. A specific crystal orientation in which size effect of electrical resistivity weakens due to anisotropy of Fermi velocity in the metal is substantially parallel to a current direction in at least a part of the crystal grains in each of the wires.

Before description of embodiments of the present invention, the background in which the present invention has been achieved by the inventor will be described.

It is known that, when the miniaturization of a metal wire progresses, the electric resistance increases more than the decrease in the cross-sectional area of the wire. This is because, as the miniaturization progresses, the effect of interface scattering of free electrons on wire's surface in electrical characteristics manifests itself and the electric resistivity, which is essentially constant in large crystal structure, increases. The phenomenon is referred to as “size effect of electrical resistivity” and well known.

The size effect of electrical resistivity occurs when the width or height of the wire is nearly equal to or less than the mean free path (MFP) (the average distance travelled by the free electrons without being scattered) of the free electrons carrying the current. The mean free path depends on the material (the constitute element, and the crystal structure) and the temperature. The value is about 10 to 50 nm at room temperatures. The minimum size of the wire used for an existing semiconductor integrated circuit is already equal to or less than the MFP in product level. Thus, the miniaturization rapidly increases the resistance of the wire. The electric signal delay in the wire caused by the rapid increase in the resistance increasingly dominates the performance of the whole circuit.

There is another problem that the progress of the miniaturization deteriorates the tolerance to the electromigration or the tolerance to the dielectric strength voltage between the wires. The realization of the decrease in the resistance and in the capacitance of the metal wire and the increase in the reliability is recognized as a challenge to be addressed in the development of next-generation semiconductor integrated circuits.

Polycrystalline copper (Cu) is generally used as a metal of the lowest wire layer (the wire layer nearest to the semiconductor substrate) that is mostly miniaturized in an existing semiconductor integrated circuit. Cu has a lower bulk resistivity and a higher tolerance for the electro migration than aluminum (Al) that has commonly been used in the past. These merits has progressed the introduction of Cu to semiconductor integrated circuits. However, the MFP of the free electrons in Cu is longer than that in Al. Thus, there is a problem that Cu is easily affected by the size effect, especially, in a miniaturized wire. A Cu wire is normally produced in a damascene process (a process in which an insulating layer is etched and Cu is embedded therein). As the miniaturization of the wire progresses, the miniaturization of the crystal grain progresses. The miniaturization of the crystal grain facilitates the size effect.

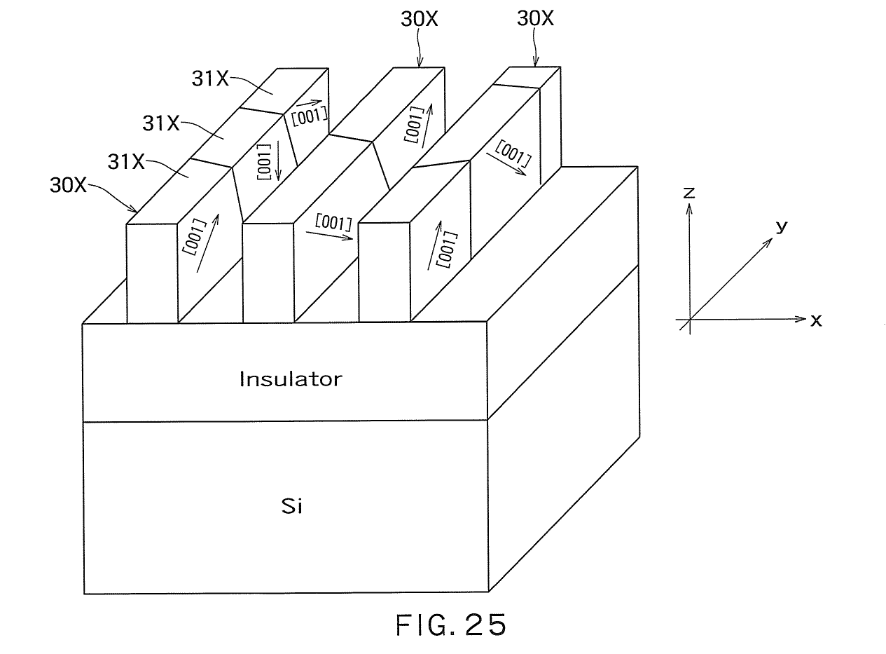

FIG. 25 is a perspective view of a part of a semiconductor device in a comparative example. As illustrated in FIG. 25, crystal grains 31X included in a wire 30X are generally orientated substantially randomly.

It is currently reported that patterning a miniaturized wire made of single crystal tungsten (W) having a body-centered cubic lattice (hereinafter, referred to as bcc) structure is performed such that the wire-length direction (the direction in which the current flows) is parallel to a <111> crystal orientation so that it can reduce the size effect of electrical resistivity. It is qualitatively explained that the phenomenon occurs because the Fermi velocity distribution (the velocity distribution of the free electrons travelling in a metal) of a W crystal has anisotropy and that causes the size effect of electrical resistivity to have the anisotropy therewith. Considering the Fermi velocity distribution of a W crystal, the anisotropy of velocity distribution on an octahedral Fermi surface is especially strong. The Fermi velocity is the velocity of the electrons that carry the current in a metal. Thus, if the distribution of the velocity has anisotropy, the frequency of collisions of the electrons with the interface of the wire can also have anisotropy.

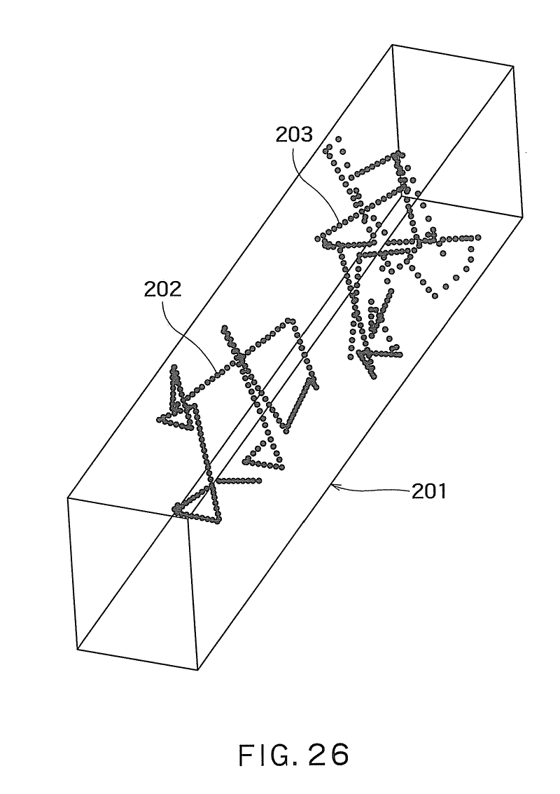

The inventor has developed a Monte Carlo simulator for electron transport in metal. The Monte Carlo simulator considers the anisotropy of the Fermi velocity distribution of the W crystal obtained from a first principle calculation. The Monte Carlo simulator quantitatively reproduces the anisotropy of the size effect of electrical resistivity on the W crystal successfully. The Monte Carlo simulation is a type of particle simulations. As illustrated in FIG. 26, the movements of the electrons in a device 201 (a process of a drift motion of the electrons in an electric field and a process in which the electrons are scattered while colliding with the interface) are simulated as trajectories 202 and 203. This can accurately calculate the electric resistance in the input shape of the wire.

The inventor has incorporated the function for determining the velocity vectors of the electrons according to the W-crystal-specific Fermi velocity distribution in the Monte Carlo simulator for metal wires by applying a full-band Monte Carlo technique in the same manner as Monte Carlo method for a semiconductor device.

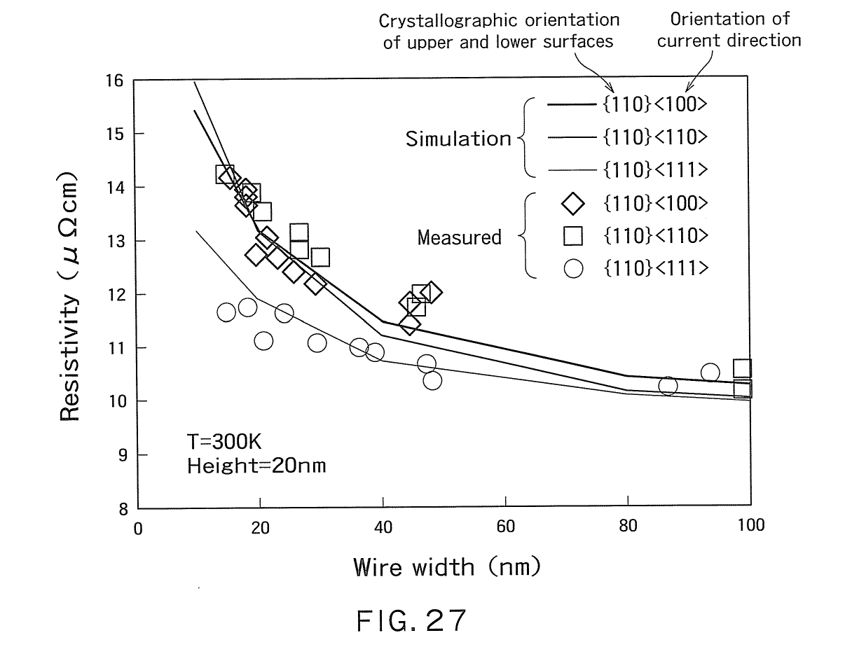

FIG. 27 is a view of the comparison of electrical resistivity between the simulation results obtained by the Monte Carlo simulator and the actual measured values. The actual measured values show that when the wire-length direction (the current direction) is parallelized to the <111> crystal orientation, the size effect weakens and this effect reduces the resistivity. The simulation quantitatively reproduces this phenomenon.

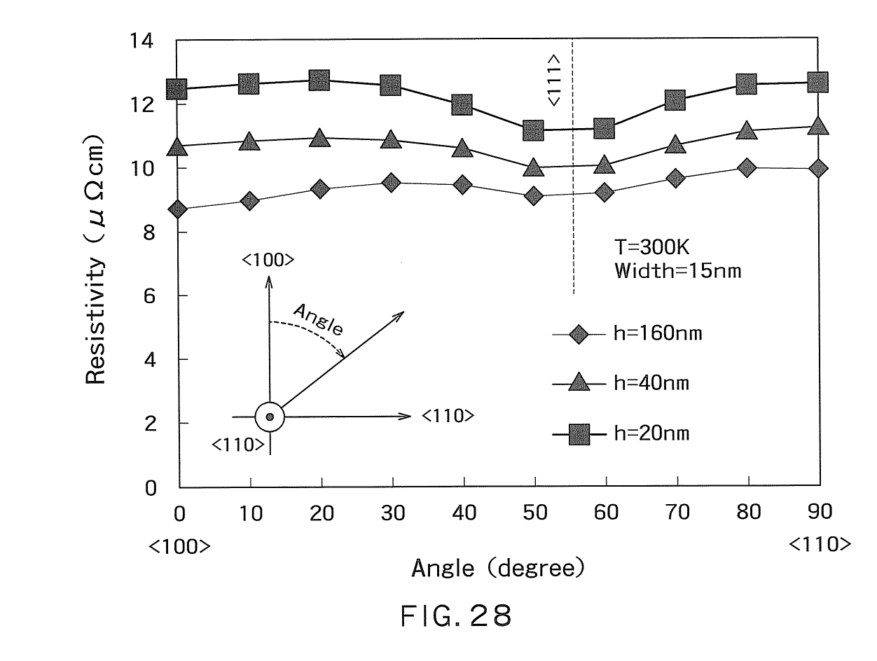

From the simulation, the inventor has further obtained important knowledge that the crystal orientation in which the size effect is reduced is not identified only according to the crystal structure. FIG. 28 is a view of the simulation result of the variation of the resistivity when the crystal orientation of the W crystal is rotated from a [100] direction to a [011] direction on a surface. FIG. 28 illustrates the dependence of the size effect of electrical resistivity on the crystal orientation of the wires having a height h=20 nm, a height h=40 nm, and a height h 160 nm, respectively. In the result, for the wire having the height h=20 nm, the lowest resistivity of the wire can be obtained when the wire-length direction of the wire is parallel to the <111> crystal orientation, similarly to the graph in FIG. 27.

On the other hand, as the height h of the wire increases, the resistivity in the <100> direction rapidly decreases. The resistivity in the <100> direction is minimized when the wire has the height h=160 nm. It can be considered that the phenomenon occurs because the anisotropy of the Fermi velocity distribution causes the wire parallel to the <100> direction to have a low size effect in the width direction (or have a small velocity component of electron in the width direction) and to have a high size effect in the height direction (or have a large velocity component of electron in the height direction). In other words, in the wire of which length direction is parallel to the <100> direction, as the height increases, the size effect in the height direction weakens and thus the resistivity decreases.

As described above, in a miniaturized wire made of a single crystal metal, the size effect of electrical resistivity has anisotropy according to the anisotropy of the crystal-specific Fermi velocity. The crystal orientation in which the size effect of electrical resistivity weakens is not identified according to the material but it depends on the shape and size of the cross-sectional surface and the crystal orientation of the surface of the wire. As for the anisotropy of the size effect of electrical resistivity in a single crystal, only the report about the anisotropy at a liquid nitrogen temperature and in an Al crystal in a millimeter-scale order is known. Only the experimental result of the miniaturized W wire is reported as an experimental result of a miniaturized wire at a room temperature.

The inventor invented the present invention based on their unique knowledge as described above. In other words, the inventors implements a miniaturized wire with a low resistance in which the size effect of electrical resistivity is weaken using noble metal (Cu, Ag, or Au), Al or Mo based on the knowledge obtained from the Monte Carlo simulation in consideration of the anisotropy of the Fermi velocity distribution in the metal crystal.

Hereinafter, embodiments of the present invention will be described with reference to the drawings. The embodiments do not limit the present invention.

### First Embodiment

The first embodiment relates to a Cu wire in which the upper surfaces and lower surfaces of main crystal grains are substantially orientated to a {100} surface.

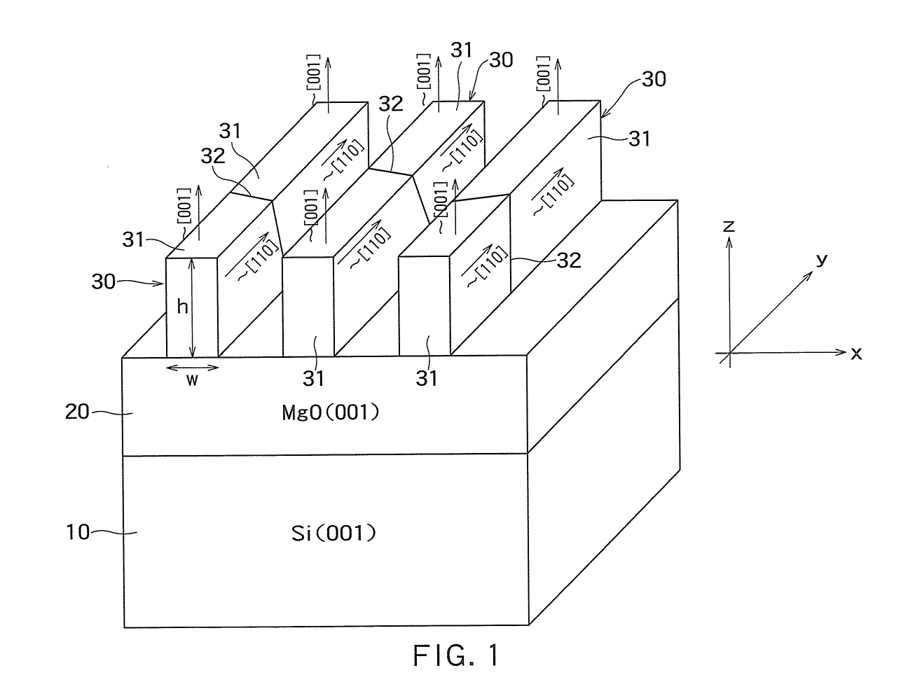

FIG. 1 is a perspective view of a part of a semiconductor device according to the first embodiment. As illustrated in FIG. 1, the semiconductor device includes an Si(001) substrate (semiconductor substrate) 10, an MgO(001) layer (insulating layer) 20, and a plurality of wires 30.

In FIG. 1, the directions that are parallel to the upper surface of the Si(001) substrate 10 and are perpendicular to each other are an x-direction and a y-direction. The direction perpendicular to the upper surface of the Si(001) substrate 10 is a z-direction.

The MgO(001) layer 20 is provided on the Si(001) substrate 10.

The wires 30 are provided on the MgO(001) layer 20 and extend in the y-direction. The average width of each of the wires 30 and the average interval between the adjacent wires 30 and 30 are nearly equal to or less than the mean free path of the free electrons in a Cu bulk crystal. In other words, each of the wires 30 has a size in which the size effect of electrical resistivity described above can occur. The cross-sectional surface of each of the wires 30 has an aspect ratio (height h/width w) of four or less.

The wires 30 each have a plurality of Cu crystal grains 31. The crystal grains 31 are arranged in the y-direction in each of the wires 30. A crystal grain boundary 32 exists between the crystal grains 31 and 31. Each of the wires 30 can be made of the single crystal grain 31.

FIG. 1 illustrates a part of the main part of each of the wires 30. The main part is a part in which the resistivity needs to be reduced in the wire 30. The main part of the wire 30 can be the whole wire 30.

The crystal grains 31 in the main part of each of the wires 30, namely, at least a part of the crystal grains 31 in each of the wires 30 are Cu crystal grains (Cu{100} crystal grains) having a face-centered cubic lattice (hereinafter, referred to as fcc) structure orientated to a (001) surface. In other words, the crystal faces on the upper surfaces and lower surfaces of the crystal grains 31 in the main part of each of the wires 30 are substantially orientated to a {100} surface. The {100} surface is the crystal face equivalent to a (100) surface. Hereinafter, the Cu{100} wire means a Cu wire in which the crystal faces on the upper surfaces and lower surfaces of the crystal grains 31 in the main part are substantially orientated to the {100} surface.

As described above, the crystal face on the upper surface of the Si(001) substrate 10, the crystal face on the upper surface of the MgO(001) layer 20, and the crystal faces on the upper surfaces of the crystal grains 31 in the main part of each of the wires 30 are substantially equivalent.

The specific crystal orientation in which the size effect of electrical resistivity weakens due to the anisotropy of the Fermi velocity in Cu, is substantially parallel to a current direction in which the current flows (the length direction of the wire 30 (the y-direction)) in the crystal grains 31 in the main part of each of the wires 30, namely, in at least a part of the crystal grains 31 in each of the wires 30. In the present embodiment, the specific crystal orientation is a <110> crystal orientation. The <110> crystal orientation is equivalent to a [110] direction.

In each of the wires 30, the current direction is not limited to the specific crystal orientation in the parts except for the main part and can be an arbitrary direction.

In each of the wires 30, the average crystal grain size of the crystal grains 31 in the current direction is larger enough than the mean free path of the free electrons in the Cu bulk crystal. In other words, the average crystal grain size is large enough to ignore the deterioration of the resistivity due to the crystal grain boundary 32.

In the present embodiment, the wire 30 has a rectangular cross-sectional shape. However, the cross-sectional shape can have a tapered structure or an inverted tapered structure. Alternatively, the corners of the wire 30 can be rounded.

Although not illustrated in the drawings, the semiconductor device can have a metal barrier layer, an insulating layer, a vacuum layer, or a layered structure including these layers between the wires 30 and 30 to prevent Cu atoms from diffusing.

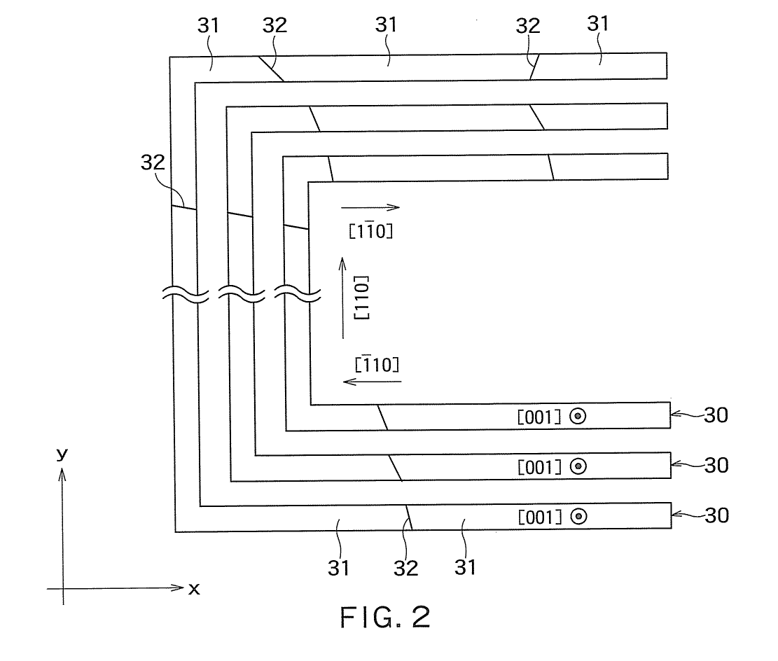

FIG. 2 is a top view of a part of the semiconductor device in the first embodiment. When the wire 30 is bent, bending the wire 30 in a direction of ±90 degree (in that case, the x-direction or a −x-direction) as illustrated in FIG. 2 can cause the current direction to be substantially parallel to the <110> direction.

### [Manufacturing Method]

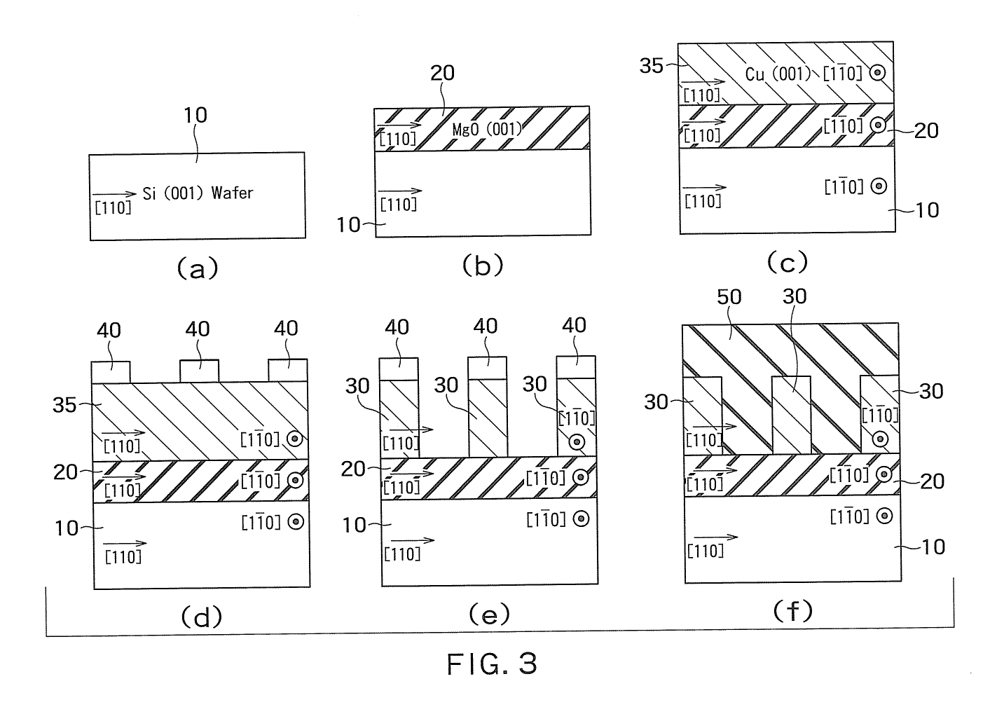

FIGS. 3(a) to 3(f) are cross-sectional views describing a process for manufacturing the semiconductor device in FIG. 1.

As illustrated in FIG. 3(a), the Si(001) substrate 10 is prepared first. As illustrated in FIG. 3(b), next, the MgO(001) layer 20 is epitaxial grown on the Si(001) substrate 10 in an ultrahigh vacuum Molecular Beam Epitaxy (MBE) method. The epitaxial growth causes the crystal orientations on the upper surfaces of the crystal to be parallel to each other on the Si(001) substrate 10 and the MgO(001) layer 20, in other words, Si[100]//MgO[100] holds.

As illustrated in FIG. 3(c), next, Cu is epitaxial grown with vacuum magnetron spattering to deposit a metal layer 35 that is a Cu(001) crystal on the MgO(001) layer 20. The epitaxial growth of Cu that is a noble metal on the MgO(001) layer 20 facilitates the crystal growth such that MgO[100]//Cu[100] holds. As a result, Si[100]//Cu[100] holds. At that time, if the orientation in the in-plane direction does not drastically change, a crystal grain boundary due to the imperfection of the process can be generated in the metal layer 35.

As illustrated in FIGS. 3(d) and 3(e), next, the shapes of the wires are patterned with photolithography and etching. An Si substrate normally has an orientation flat (or notch) that is a mark showing a (011) crystal orientation so as to specify the crystal orientation in the wafer plane. Thus, the <110> direction that is the specific crystal orientation is specified according to the relationship between the orientation flat (or notch) and the crystal orientations in the MgO(001) layer 20 and the metal layer 35. As illustrated in FIG. 3(d), masks 40 are patterned such that the average width of each of the wires 30 and the average interval between the adjacent wires 30 and 30 are nearly equal to or less than the mean free path of the free electrons in the Cu bulk crystal of the metal layer 35, and such that the current direction is substantially parallel to the <110> direction in the main part of the wire 30.

After that, as illustrated in FIG. 3(e), the metal layer 35 is etched using the masks 40 as protective films to form the wires 30. At that time, the MgO(001) layer 20 can also be etched. This prevents the MgO(001) layer 20 that is a high-k film from existing between the adjacent wires 30 and 30 and thus can reduce the wiring capacitance between the wires 30 and 30.

Next, as illustrated in FIG. 3(f), after the masks 40 are removed, an insulating film 50 is formed on the MgO(001) layer 20 and the wires 30 to protect the wires 30.

In the production method described above, the wires 30 in which the current direction (length direction) is orientated to the <110> direction can be produced.

### [Effect]

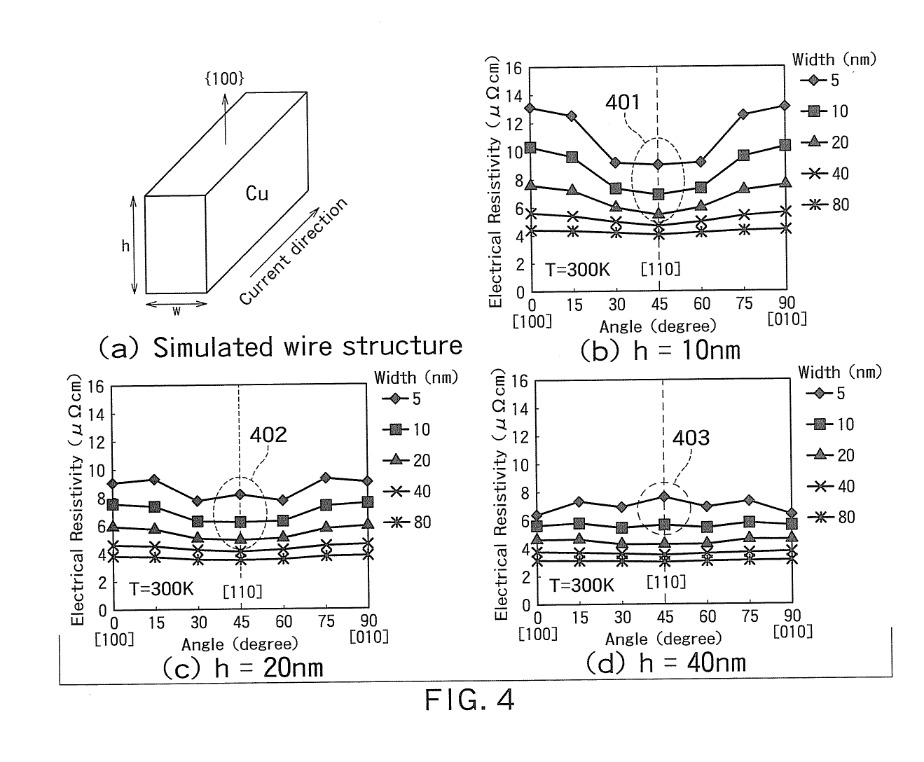

FIG. 4 is a view of the simulation result of the dependence of the resistivity of a single crystal Cu{100} wire on the crystal orientation. As illustrated in FIG. 4(a), the wire 30 in the simulation has a rectangular cross-sectional shape. It is assumed that the crystal faces on the upper surface and lower surface of the wire 30 are the {100} surfaces. It is also assumed that the electrons colliding with the interface of the wire 30 are randomly scattered so as to have the velocity component separating from the interface in the Monte Carlo simulation.

FIGS. 4(b), 4(c), and 4(d) plot the resistivity of the wire 30 having the heights h of 10 nm, the resistivity of the wire 30 having the heights h of 20 nm, and the resistivity of the wire 30 having the heights h of 40 nm, respectively, when each of the crystal orientations is rotated to a [010] direction based on the wire in a [100] direction in the (001) surface. As shown in the drawings, the crystal orientation in which the resistivity has the minimum value varies depending on the height h and width w of the wire 30. When the aspect ratio is equal to or less than four and the width is narrow (characteristics 401 and 402), the resistivity is lowered within a range of ±15 degrees from a [110] direction (45 degree on the horizontal axis). The present embodiment can reduce the resistivity using the characteristics.

On the other hand, when a miniaturized wire has the aspect ratio exceeding 4, for example, when w=5 nm or 10 nm holds (a characteristic 403) in FIG. 4(d), the anisotropy of the size effect varies and the direction in which the resistivity is low disappears.

As described above, in the present embodiment, the current easily flows in the current direction because the cross-sectional surface of the wire 30 has an aspect ratio of four or less and the specific crystal orientation (the <110> crystal orientation) in which the size effect of electrical resistivity weakens is substantially parallel to the current direction. This suppresses the size effect of electrical resistivity and thus can reduce the wire resistance to the resistance lower than that of a conventional wire having the same cross-sectional surface area.

Note that a wire 30 made of a single crystal grain 31 but without a crystal grain boundary 32 does not cause Cu atoms to diffuse on the crystal grain boundary 32. This can improve the tolerance to the electromigration and thus can increase the reliability.

FIG. 3 illustrates the manufacturing process using the MgO(001) layer 20 as an insulating layer. However, an insulating or metallic barrier film for preventing Cu from diffusing and improving the reliability can be deposited between the MgO(001) layer 20 and the metal layer 35 as long as the crystal grains 31 orientated as illustrated in FIG. 1 can be grown.

Furthermore, another insulating material or semi-insulating material can be used as the insulating layer instead of the MgO(001) layer 20 as long as the crystal grains 31 orientated as illustrated in FIG. 1 can be grown. For example, a substrate such as sapphire substrate having a high crystallinity can be used as the insulating layer.

Furthermore, a vacuum layer can be inserted between the adjacent wires 30 and 30. This can reduce also the capacitance between the wires.

### Second Embodiment

The second embodiment relates to a Cu{110} wire.

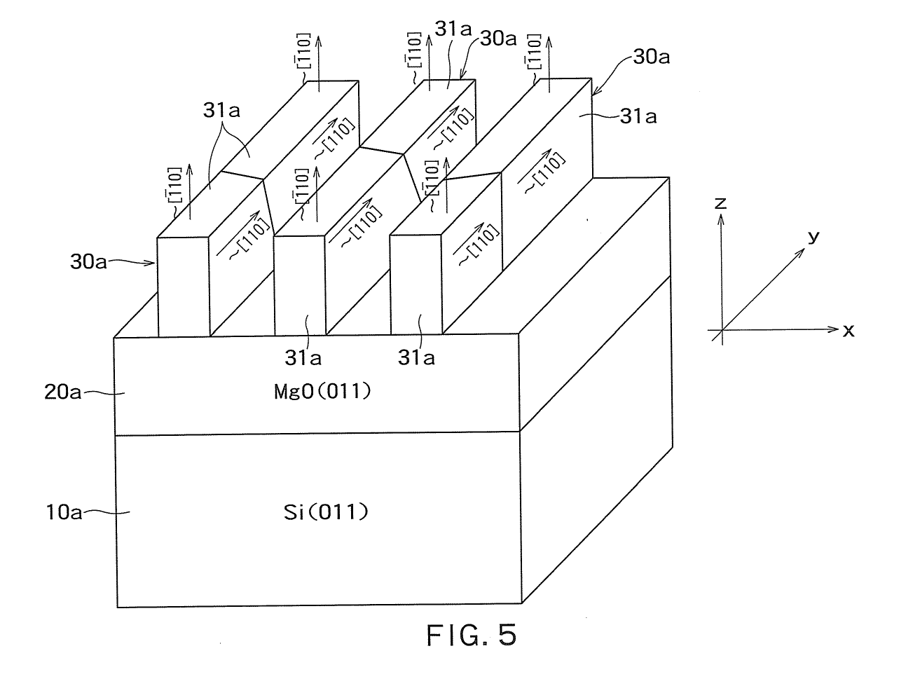

FIG. 5 is a perspective view of a part of a semiconductor device according to the second embodiment. As illustrated in FIG. 5, the semiconductor device includes an Si(011) substrate 10a, an MgO(011) layer 20a, and a plurality of wires 30a.

As for the wires 30a in the second embodiment, different from the first embodiment, the crystal grains 31a in the main part of each of the wires 30a are Cu{110} crystal grains each having an fcc structure, and the crystal faces on the upper surfaces and lower surfaces of the crystal grains 31a are substantially orientated to a {110} surface, and also the cross-sectional surface of each of the wires 30a has an arbitrary aspect ratio.

The current direction is the same as in the first embodiment. A specific crystal orientation (the <110> crystal orientation) in which the size effect of electrical resistivity weakens is substantially parallel to the current direction in the main part of each of the wires 30a.

The crystal grain size of the crystal grains 31a, the average width of each of the wires 30a, and the average interval between the wires 30a and 30a are the same as those in the first embodiment.

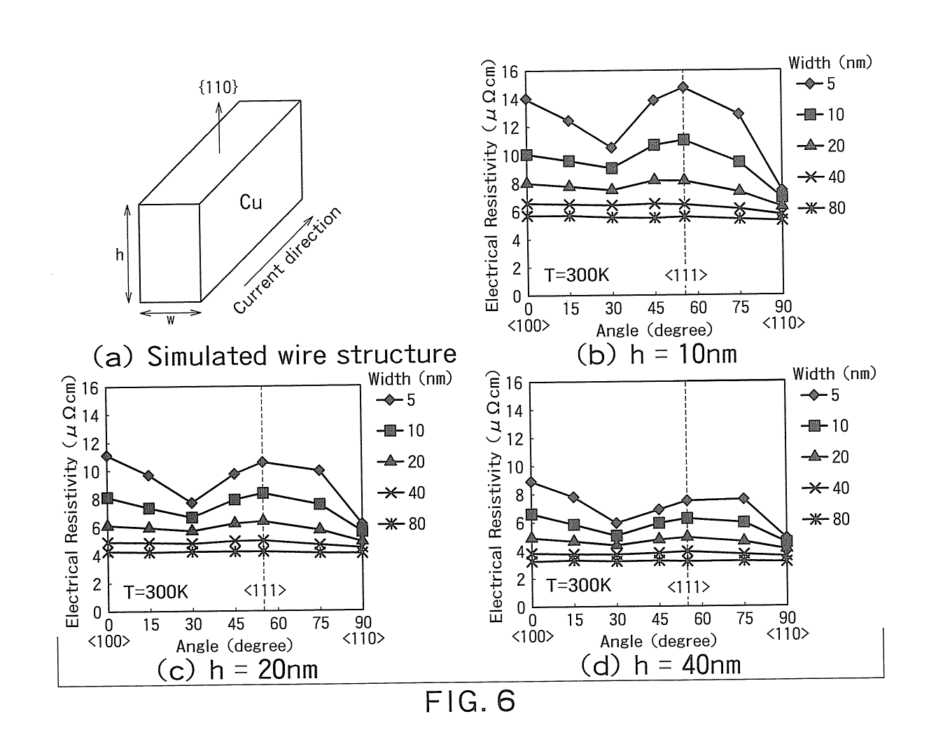

FIG. 6 is a view of the simulation result of the dependence of the resistivity of a single crystal Cu{110} wire on the crystal orientation. FIGS. 6(b), 6(c), and 6(d) plot the resistivity of the wire 30a having the height h of 10 nm, the resistivity of the wire 30a having the height h of 20 nm, and the resistivity of the wire 30a having the height h of 40 nm, respectively, when each of the crystal orientations is rotated to a <110> direction based on the wire in a <100> direction in a (011) surface. As shown in the drawings, the single crystal Cu{110} wire has the minimum resistivity in the [110] direction, similarly to the single crystal Cu{100} wire (FIG. 4) in the first embodiment. However, the crystal orientation in which the resistivity is minimized does not depend on the aspect ratio of the wire 30a.

Arranging the <110> crystal orientation of each of the crystal grains 31a substantially in parallel to the current direction as described above can suppress the size effect of electrical resistivity and thus can reduce the resistance of the wire 30a using Cu.

### Third Embodiment

In the third embodiment, silver (Ag) or gold (Au) is used instead of Cu in the first or second embodiment.

The semiconductor device has the same structure as in the first or second embodiment. Thus, the drawing and the description will be omitted. Hereinafter, the different points from the first or second embodiment will mainly be described.

The Fermi surfaces of the fcc crystals of Ag and Au have very similar structures to the structure of Cu that is in the same group as Ag and Au in the periodic table. Thus, the anisotropy of the size effect of electrical resistivity of a wire using Ag or Au is similar to the anisotropy of the size effect of electrical resistivity of Cu.

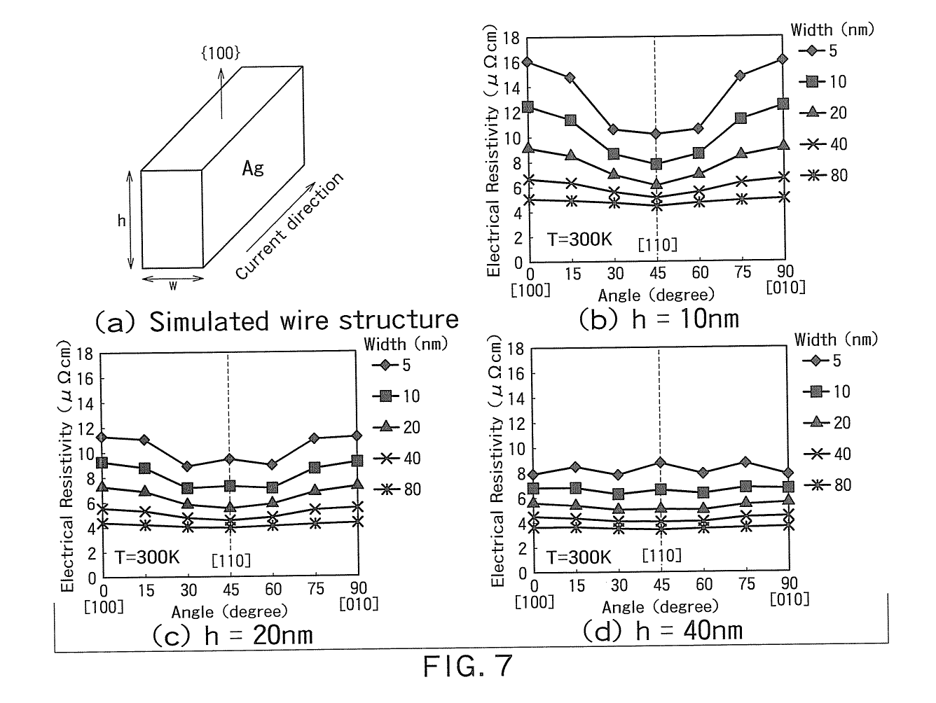

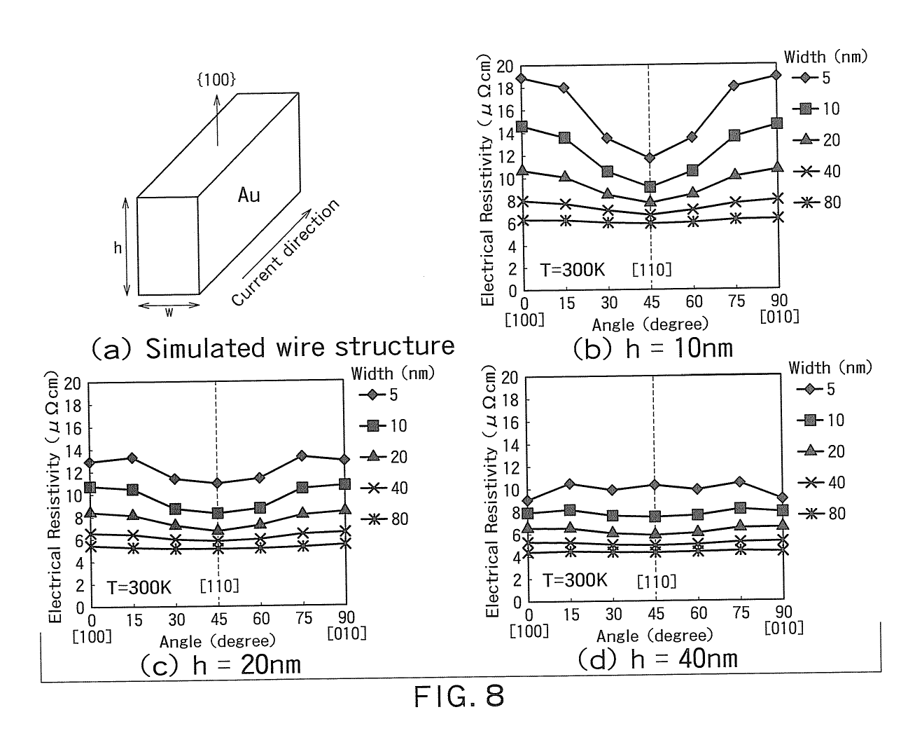

FIG. 7 is a view of the simulation result of the dependence of the resistivity of a single crystal Ag{100} wire on the crystal orientation. FIG. 8 is a view of the simulation result of the dependence of the resistivity of a single crystal Au{100} wire on the crystal orientation.

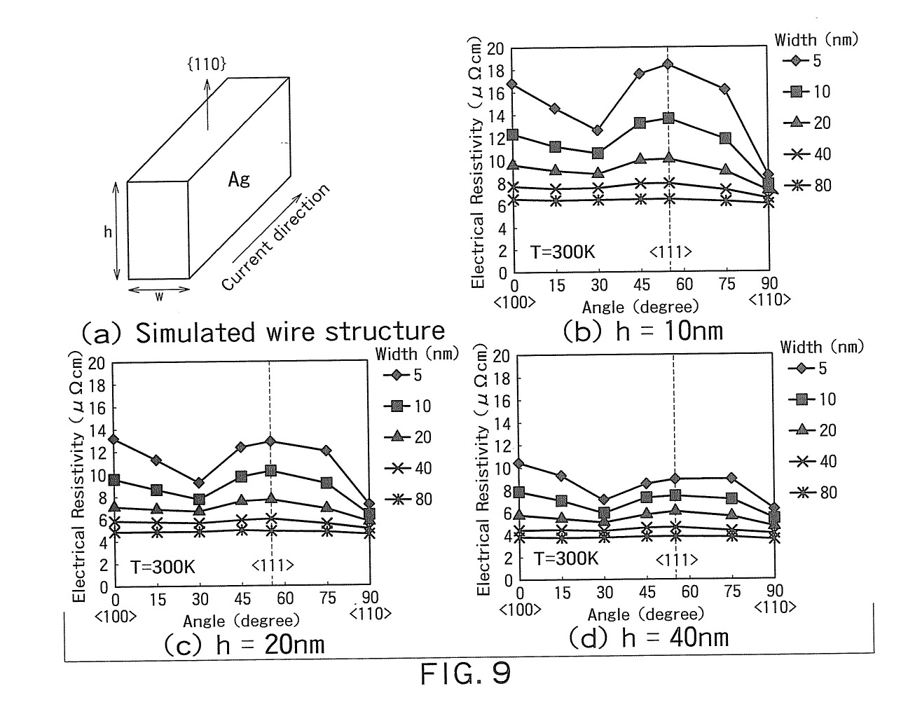

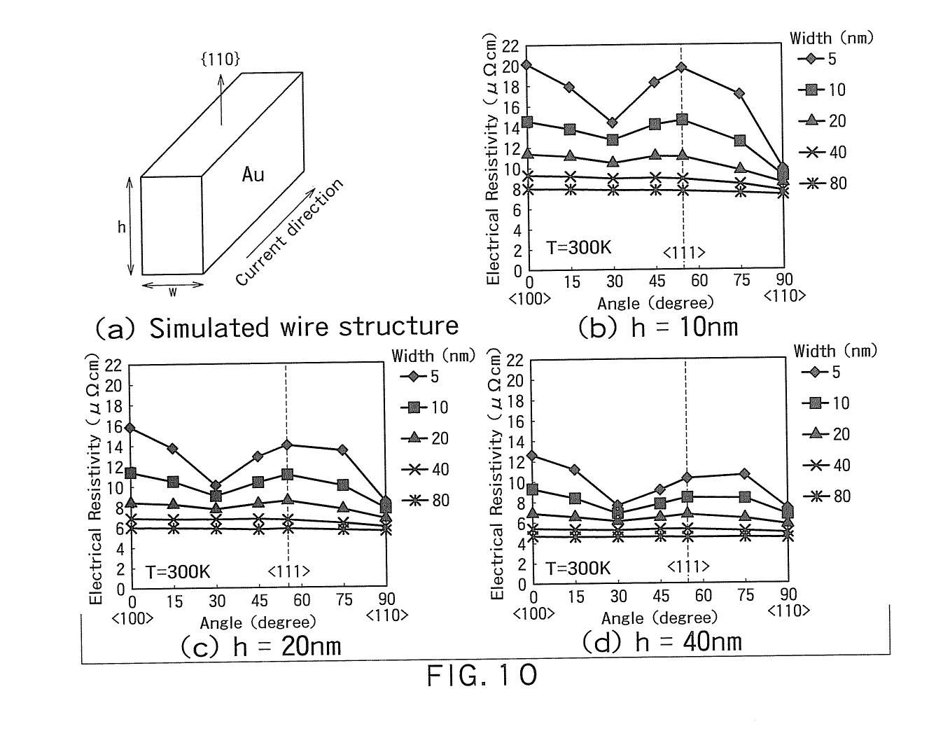

FIG. 9 is a view of the simulation result of the dependence of the resistivity of a single crystal Ag{110} wire on the crystal orientation. FIG. 10 is a view of the simulation result of the dependence of the resistivity of a single crystal Au{110} wire on the crystal orientation.

As illustrated in FIGS. 7 and 8, similarly to the single crystal Cu{100} wire, when the cross-sectional surface of each of the single crystal Ag{100} wire and the single crystal Au{100} wire has an aspect ratio of four or less, the resistivity is lowered at the <110> crystal orientation.

Thus, similarly to the first embodiment, the aspect ratio of the wire 30 is set at four or less and the <110> crystal orientation of each of the crystal grains 31 is arranged substantially in parallel to the current direction. This can suppress the size effect of electrical resistivity and reduce the resistance of the wire 30 using Ag or Au.

As illustrated in FIGS. 9 and 10, similarly to the single crystal Cu{110} wire, the resistivity of each of the single crystal Ag{110} wire and the single crystal Au{110} wire is lowered at the <110> crystal orientation regardless of the aspect ratio of each of the wires.

Thus, similarly to the second embodiment, arranging the <110> crystal orientation of each of the crystal grains 31a substantially in parallel to the current direction as described above can suppress the size effect of electrical resistivity and thus can reduce the resistance of the wire 30a using Ag or Au.

### Fourth Embodiment

The fourth embodiment relates to an Al{100} wire.

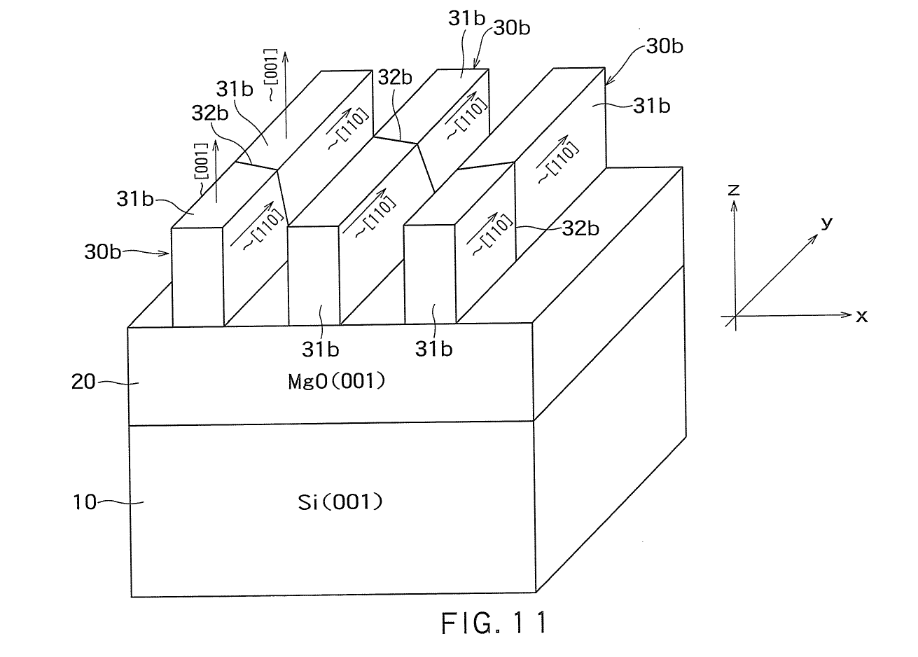

FIG. 11 is a perspective view of a part of a semiconductor device according to the fourth embodiment. In FIG. 11, the same reference signs are put to the components in common with FIG. 1 illustrating the first embodiment. Hereinafter, the different points will mainly be described.

The crystal grains 31b in the main part of each of the wires 30b are Al{100} crystal grains each having an fcc structure. In other words, the crystal faces on the upper surfaces and lower surfaces of the crystal grains 31b in the main part of each of the wires 30b are orientated substantially to a {100} surface. In the crystal grains 31b in the main part of the wire 30b, the <110> crystal orientation that is a specific crystal orientation is substantially parallel to a current direction.

The cross-sectional surface of each of the wires 30b has an aspect ratio of two or more. The average width of each of the wires 30b and the average interval between the wires 30b are nearly equal to or less than the mean free path of the free electrons in an Al bulk crystal. In each of the wires 30b, the average crystal grain size of the crystal grains 31b in the current direction is larger enough than the mean free path of the free electrons in the Al bulk crystal. In other words, the average crystal grain size is large enough to ignore the deterioration of the resistivity due to the crystal grain boundary 32b.

In the single crystal Al wire, the anisotropy of the size effect of electrical resistivity is generated due to the anisotropy of the Fermi velocity.

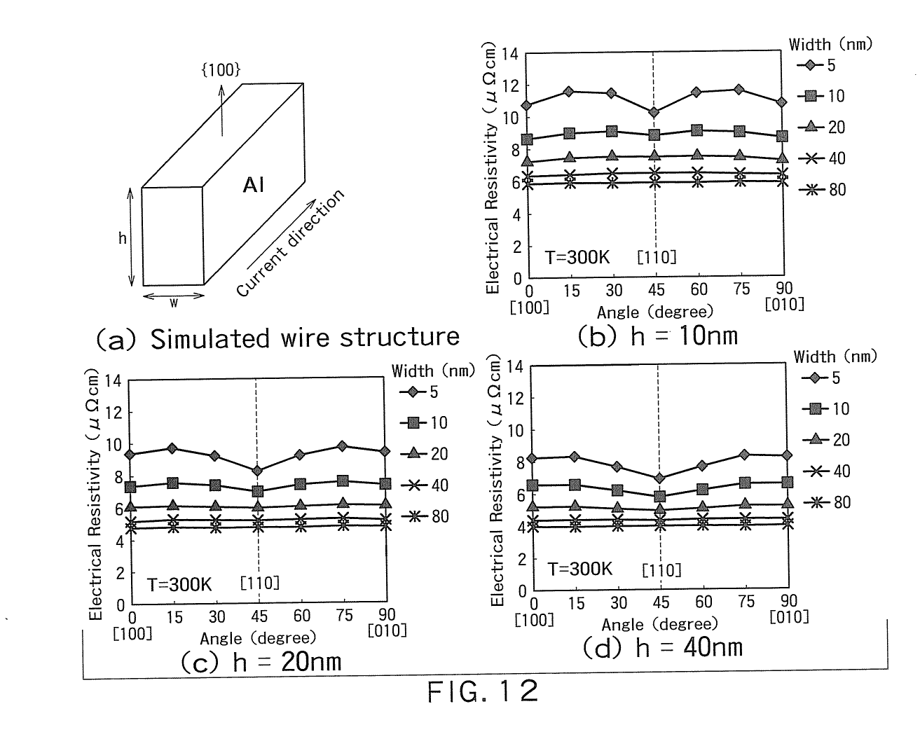

FIG. 12 is a view of the simulation result of the dependence of the resistivity of a single crystal Al{100} wire on the crystal orientation. As illustrated in FIGS. 12(b), 12(c), and 12(d), especially when the single crystal Al{100} wire has an aspect ratio of two or more, the resistivity lowers in the <110> direction.

Thus, as described above, the aspect ratio of the wire 30b is set at two or more and the <110> crystal orientation of each of the crystal grains 31b is arranged substantially in parallel to the current direction. This can suppress the size effect of electrical resistivity and reduce the resistance of the wire 30b using Al.

### Fifth Embodiment

The fifth embodiment relates to an Al{110} wire.

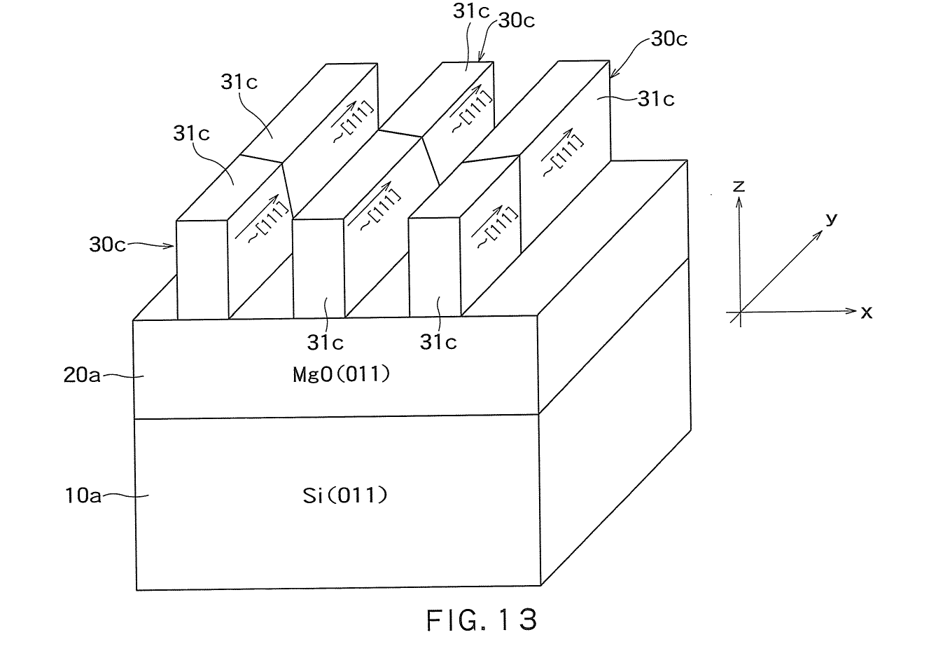

FIG. 13 is a perspective view of a part of a semiconductor device according to the fifth embodiment. In FIG. 13, the same reference signs are put to the components in common with FIG. 5 illustrating the second embodiment. Hereinafter, the different points will mainly be described.

The crystal grains 31c in the main part of each of the wires 30c are Al{110} crystal grains each having an fcc structure. In other words, the crystal faces on the upper surfaces and lower surfaces of the crystal grains 31c in the main part of the wire 30c are orientated substantially to a {110} surface.

In the crystal grains 31c in the main part of each of the wires 30c, the <111> crystal orientation that is a specific crystal orientation is substantially parallel to the current direction.

The cross-sectional surface of each of the wires 30c has an aspect ratio of two or more. The average crystal grain size, the average width of each of the wires 30c and the average interval between the wires 30c are the same as those in the fourth embodiment.

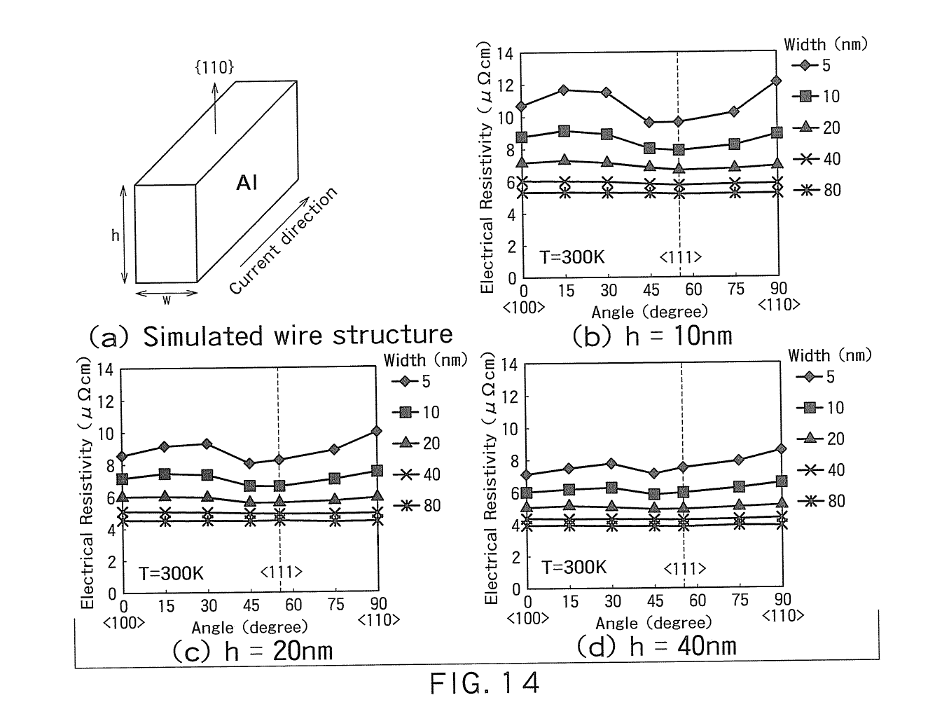

FIG. 14 is a view of the simulation result of the dependence of the resistivity of a single crystal Al{110} wire on the crystal orientation. As illustrated in FIGS. 14(b), 14(c), and 14(d), especially when the single crystal Al{110} wire has an aspect ratio of four or less, the resistivity lowers in the direction <111>.

Thus, as described above, the aspect ratio of the wire 30c is set at two or more and the crystal orientation <111> of each of the crystal grains 31c is arranged substantially in parallel to the current direction. This can suppress the size effect of electrical resistivity and reduce the resistance of the wire 30c using Al.

### Sixth Embodiment

The sixth embodiment relates to an Mo{110} wire using molybdenum (Mo).

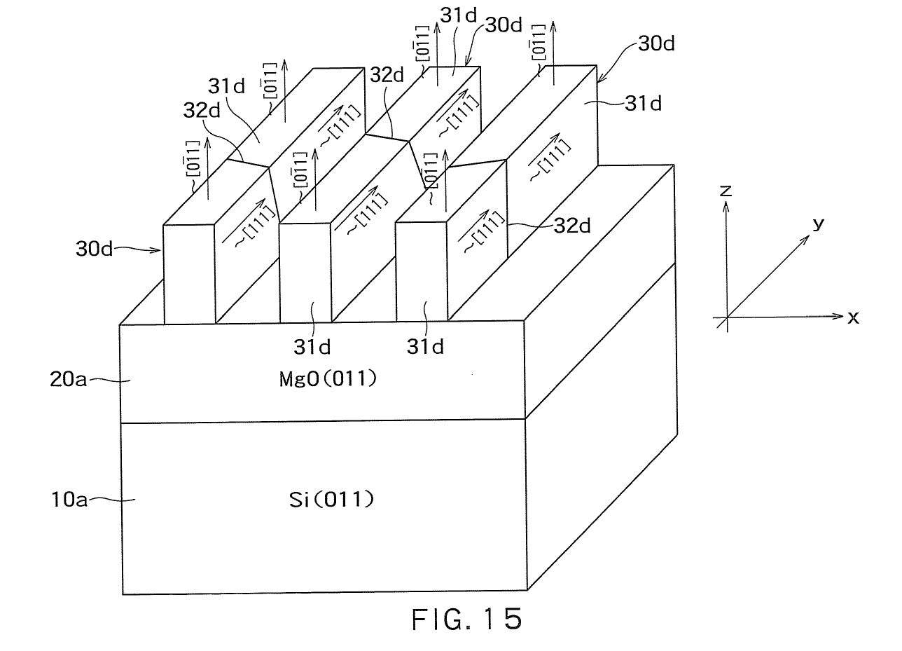

FIG. 15 is a perspective view of a part of a semiconductor device according to the sixth embodiment. In FIG. 15, the same reference signs are put to the components in common with FIG. 5 illustrating the second embodiment. Hereinafter, the different points will mainly be described.

The crystal grains 31d in the main part of each of the wires 30d are Mo{110} crystal grains each having a bcc structure. In other words, the crystal faces on the upper surfaces and lower surfaces of the crystal grains 31d in the main part of each of the wires 30d are orientated substantially to a {110} surface.

In the crystal grains 31d in the main part of each of the wires 30d, the crystal orientation <111> that is a specific crystal orientation is substantially parallel to the current direction.

The cross-sectional surface of each of the wires 30d has an aspect ratio of four or less. The average width of each of the wires 30d and the average interval between the wires 30d are nearly equal to or less than the mean free path of the free electrons in an Mo bulk crystal. In each of the wires 30d, the average crystal grain size of the crystal grains 31d in the current direction is larger enough than the mean free path of the free electrons in the Mo bulk crystal. In other words, the average crystal grain size is large enough to ignore the deterioration of the resistivity due to the crystal grain boundary 32d.

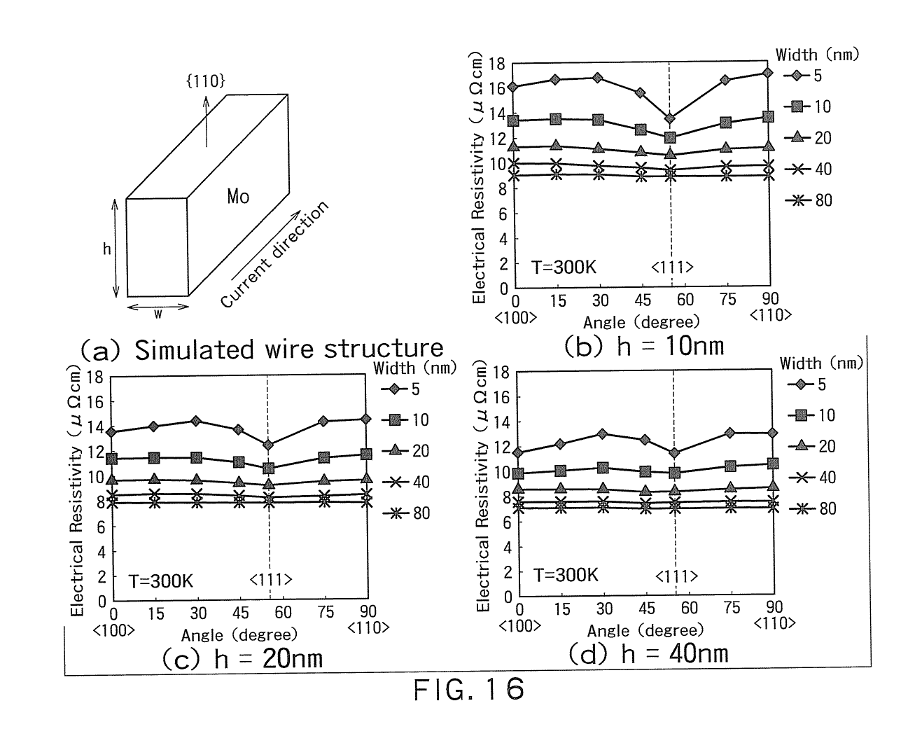

FIG. 16 is a view of the simulation result of the dependence of the resistivity of a single crystal Mo{110} wire on the crystal orientation. As illustrated in FIGS. 16(b), 16(c), and 16(d), when the single crystal Mo{110} wire has an aspect ratio of four or less, the resistivity lowers in the <111> direction.

Thus, as described above, the aspect ratio of the wire 30d is set at four or less and the crystal orientation <111> of each of the crystal grains 31d is arranged substantially in parallel to the current direction. This can suppress the size effect of electrical resistivity and reduce the resistance of the wire 30d using Mo.

### Seventh Embodiment

The seventh embodiment relates to an Mo{100} wire.

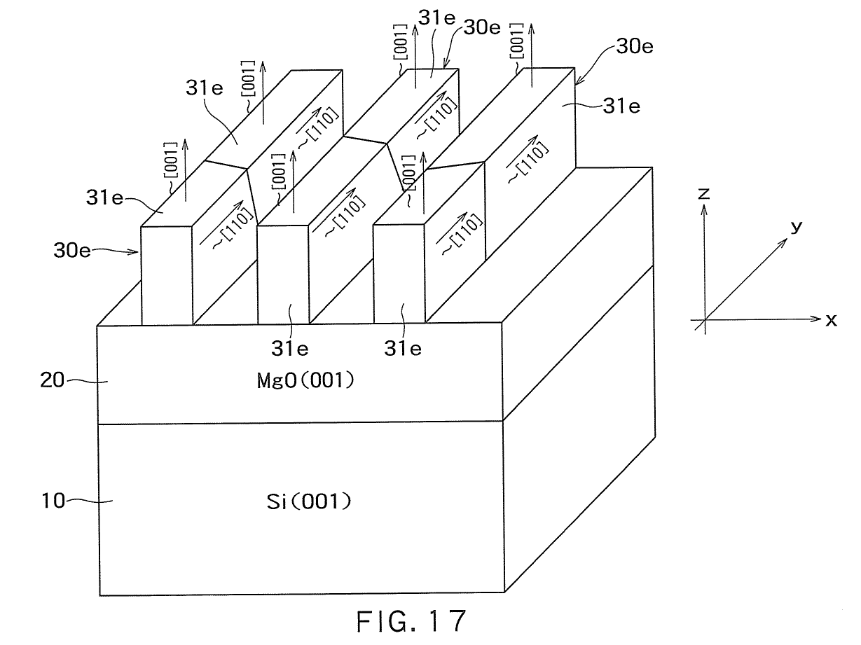

FIG. 17 is a perspective view of a part of a semiconductor device according to the seventh embodiment. In FIG. 17, the same reference signs are put to the components in common with FIG. 1 illustrating the first embodiment. Hereinafter, the different points will mainly be described.

The crystal grains 31e in the main part of each of the wires 30e are Mo{100} crystal grains each having a bcc structure. In other words, the crystal faces on the upper surfaces and lower surfaces of the crystal grains 31e in the main part of each of the wires 30e are orientated to a {100} surface.

In the crystal grains 31e in the main part of each of the wires 30e, the <110> crystal orientation that is a specific crystal orientation is substantially parallel to the current direction.

The cross-sectional surface of each of the wires 30e has an aspect ratio of two or more. The average crystal grain size, the average width of each of the wires 30e and the average interval between the wires 30e are the same as those in the sixth embodiment.

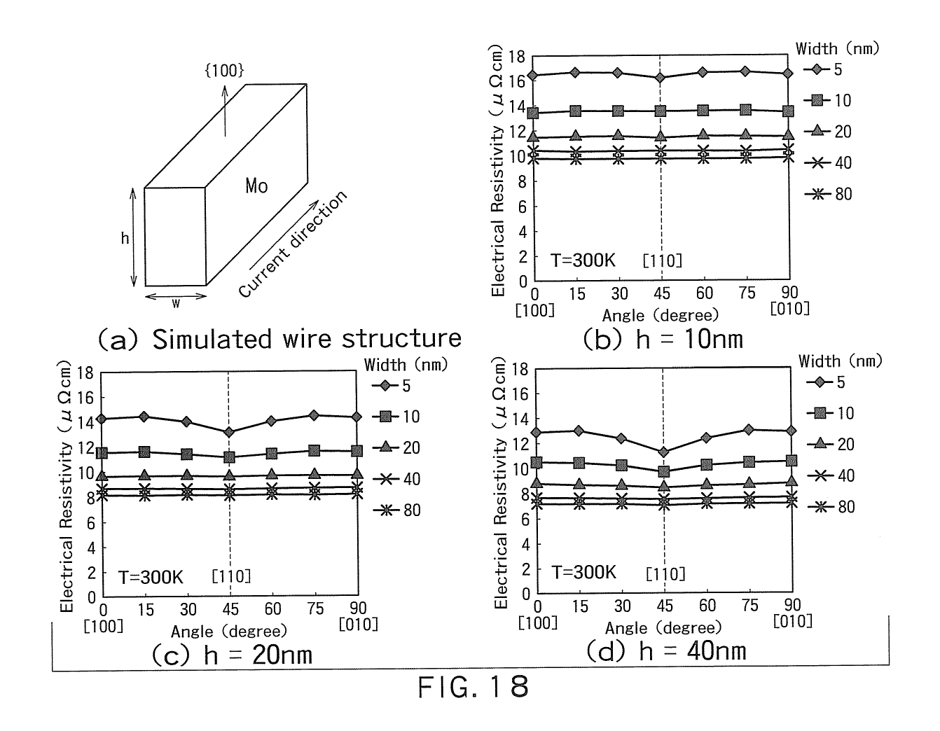

FIG. 18 is a view of the simulation result of the dependence of the resistivity of a single crystal Mo{100} wire on the crystal orientation. As illustrated in FIGS. 18(b), 18(c), and 18(d), when the single crystal Mo{100} wire has an aspect ratio of two or more, there is a region in which the resistivity lowers in the <110> direction.

Thus, as described above, the aspect ratio of the wire 30e is set at two or more and the <110> crystal orientation of each of the crystal grains 31e is arranged substantially in parallel to the current direction. This can suppress the size effect of electrical resistivity and reduce the resistance of the wire 30e using Mo.

Note that each of the variations described in the first embodiment can also be applied to the second to seventh embodiments.

### Eighth Embodiment

The eighth embodiment relates to a NAND type semiconductor storage device (flash memory) using the Cu{100} wire in the first embodiment as the bit lines.

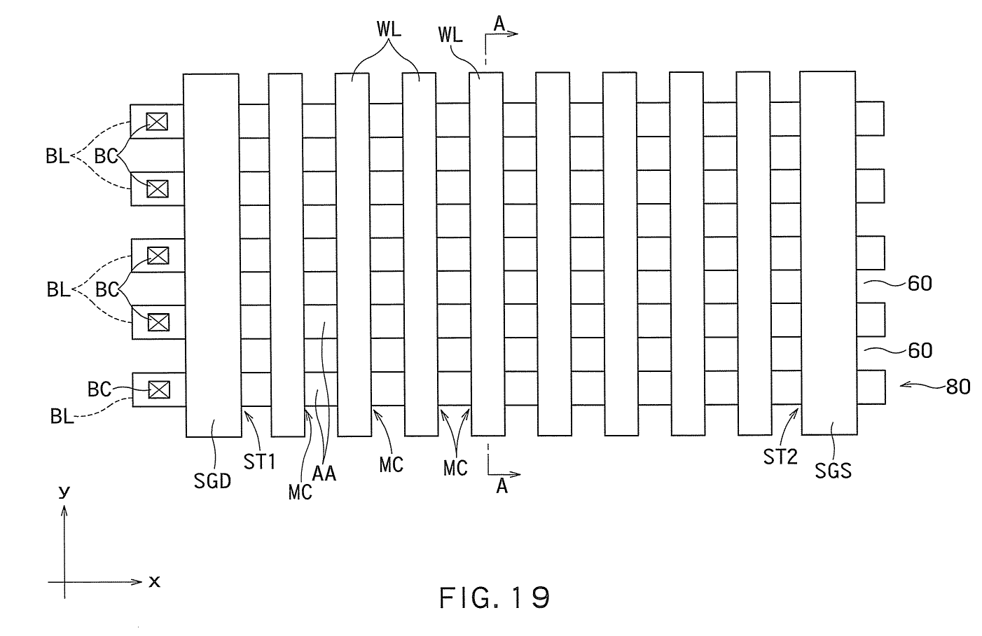

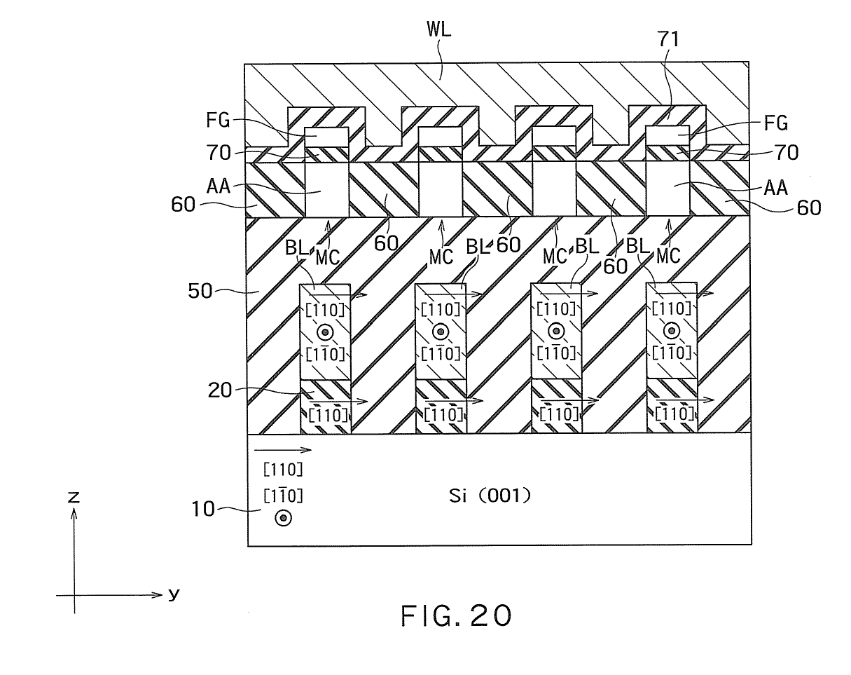

FIG. 19 is a schematic plan view of the structure of a semiconductor storage device according to the eighth embodiment. FIG. 20 is a cross-sectional view taken along line A-A in FIG. 19.

As illustrated in FIGS. 19 and 20, the semiconductor storage device includes an Si(001) substrate (semiconductor substrate) 10, an MgO(001) layer (first insulating layer) 20, a plurality of bit lines BL, a second insulating layer 50, a plurality of memory cells MC, an element isolation insulating film 60, and a plurality of word lines WL. The memory cell MC includes an active region AA, an insulating film (tunnel insulating film) 70, a floating gate FG, and an insulating film (IPD film) 71.

As illustrating FIG. 19, the active regions AA and the element isolation insulating films 60 extend in the x-direction (a first direction or a bit line direction). The active regions AA and the element isolation insulating films 60 are alternately placed in the y-direction (a second direction or a word line direction). The x-direction is substantially perpendicular to the y-direction. The word lines WL extend in the y-direction at predetermined intervals in the x-direction. Select gate lines SGD and SGS extending in the y-direction are placed so as to hold the word lines WL therebetween.

The memory cell MC is formed at the position in which the active region AA crosses the word lines WL. A select transistor ST1 is formed at the position in which the active region AA crosses the select gate line SGD. A select transistor ST2 is formed at the position in which the active region AA crosses the select gate line SGS.

As described below, the bit lines BL are provided under the active regions AA such that the active regions AA overlap with the bit lines BL. In other words, the word lines WL cross the bit lines BL.

The memory cells MC arranged in the x-direction and the select transistors ST1 and ST2 on both ends of the memory cells are included in a NAND string 80. An end of the NAND string 80, namely, the select transistor ST1 is electrically connected to the bit line BL through bit line contact BC. Although not illustrated in the drawings, the other end of the NAND string 80, namely, the select transistor ST2 is connected to a source line.

As illustrated in FIG. 20, MgO(001) layers 20 are provided on the Si(001) substrate 10 at predetermined intervals in the y-direction and extend in the x-direction.

The bit lines BL are provided on the MgO(001) layers 20 and extend in the x-direction. The MgO(001) layers 20 exist under the bit lines BL and do not exist between the adjacent bit lines BL and BL. This can reduce the wiring capacitance between the bit lines BL and BL.

Note that, when it is not necessary to reduce the wiring capacitance, the MgO(001) layers 20 can be provided without the intervals so as to cover the Si(001) substrate 10, similarly to the first embodiment.

Each of the bit lines BL has the same structure as the wire 30 in the first embodiment. In other words, each of the bit lines BL has one or more Cu crystal grains. At least a part of the crystal grains in each of the bit lines BL is Cu{100} crystal grain having an fcc structure. The average width of each of the bit lines BL and the average interval between the adjacent bit lines BL and BL are less than the mean free path of the free electrons in the Cu bulk crystal. The average interval between the adjacent bit lines BL and BL can be wider than the mean free path of the free electrons. The specific crystal orientation (a <110> crystal orientation) in which the size effect of electrical resistivity weakens due to the anisotropy of the Fermi velocity in Cu, is parallel to the x-direction in at least a part of the crystal grains in each of the bit lines BL. The cross-sectional surface of each of the bit lines BL has an aspect ratio of four or less. In each of the bit lines BL, the average crystal grain size of the crystal grains in the x-direction is larger enough than the mean free path of the free electrons in the Cu bulk crystal.

The second insulating film 50 covers the Si(001) substrate 10, the MgO(001) layer 20, and the bit lines BL. The upper portion of the second insulating film 50 is substantially flattened.

The memory cells MC are provided on the second insulating layer 50. In other words, the memory cells MC are supported with the Si(001) substrate 10.

The active regions AA of the memory cells MC are provided on the second insulating layer 50. The active regions AA are made, for example, of single crystal silicon, polysilicon, or amorphous silicon.

The element isolation insulating film 60 is provided between the adjacent active regions AA and AA. The element isolation insulating film 60 is made, for example, of a silicon oxide film.

The insulating films 70 are provided on the active regions AA. The floating gates FG are provided on the insulating films 70. The insulating film 71 is provided on the floating gates FG.

The insulating films 70 and 71 are made, for example, of a silicon oxide film, a silicon oxynitride film, or a silicon nitride film. The floating gate FG is made, for example, of polysilicon, or a metal material such as TiN.

The word line WL extending in the y-direction is provided on the insulating film 71.

Next, a method for manufacturing the semiconductor storage device will be described. First, the processes in FIGS. 3(a) to 3(f) in the first embodiment are performed. After the process in FIG. 3(f), the upper surface of the insulating film 50 is planarized.

Next, silicon is deposited on the insulating film 50. After that, similarly to the well-known manufacturing method, the silicon is processed to create the active regions AA. Next, the memory cells MC, the select transistor ST, and the like are created. After that, the bit line contacts BC and the like are created.

The present embodiment uses the wire 30 in the first embodiment as the bit line BL. This suppresses the size effect of electrical resistivity of the bit line BL, and thus can reduce the wire resistance from the conventional bit line having the same cross-sectional surface area. This can suppress the wire delay of the bit line BL.

Corresponding to an amount of which the resistance of the bit line BL is reduced, the wire width of the bit line BL can be reduced. Therefore, the rate of integration of the memory cells MC can be improved.

Note that, although the floating gate type memory cell MC has been described in the eighth embodiment, a charge trapping type memory cell can be used instead of the floating gate type memory cell MC to provide the same effect as described above.

The charge trapping type memory cell can be, for example, a MONOS type memory cell.

### Ninth Embodiment

The ninth embodiment relates to a resistance change type semiconductor storage device using the Cu{100} wire in the first embodiment.

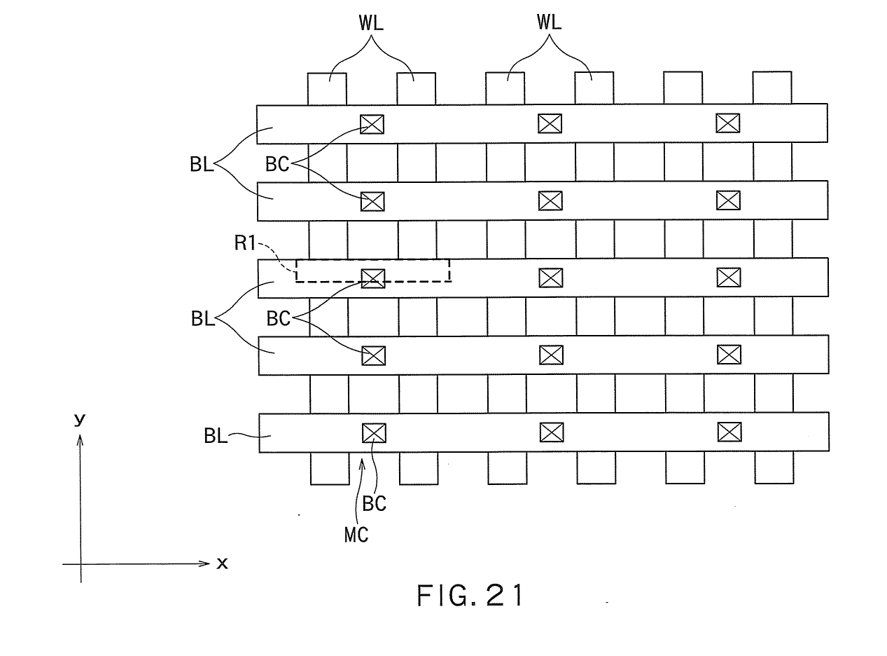

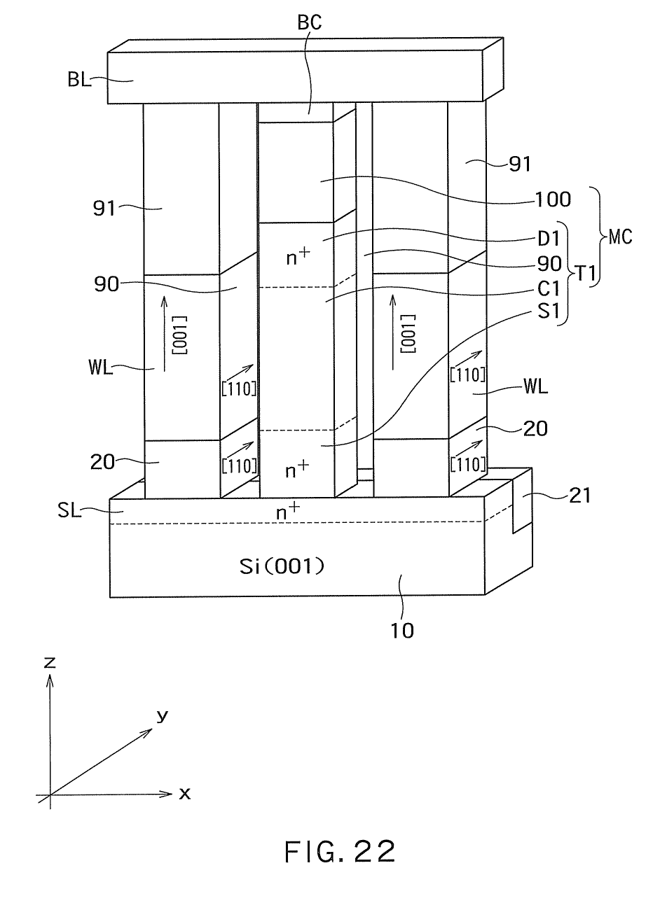

FIG. 21 is a schematic plan view of the structure of a semiconductor storage device according to the ninth embodiment. FIG. 22 is a perspective view of a region R1 in FIG. 21. The region R1 corresponds to a memory cell MC.

As illustrated in FIGS. 21 and 22, the semiconductor storage device includes an Si(001) substrate (semiconductor substrate) 10, an MgO(001) layer (first insulating layer) 20, a plurality of word lines WL, a plurality of bit lines BL, a plurality of source lines SL, and a plurality of memory cells MC. The memory cell MC is a current- or voltage-driven resistance change type memory cell (a Magnetic Random Access Memory (MRAM) cell, a Resistance random access memory (ReRAM) cell, a Conductive Bridge RAM (CBRAM) cell, or a Phase Change Memory (PCM) cell, and the like.) The memory cell MC includes a vertical field effect transistor T1 working as a select transistor, and a variable resistive layer 100. The field effect transistor T1 includes a source layer S1, a channel layer C1, a second insulating layer 90, and a drain layer D1.

As illustrated in FIG. 21, the bit lines BL extend in the x-direction (a second direction, or a bit line direction) at predetermined intervals in the y-direction (a first direction, or a word line direction). The x-direction is substantially perpendicular to the y-direction. The word lines WL extend in the y-direction at predetermined intervals in the x-direction. The word lines WL cross the bit lines BL.

The memory cell MC is provided at the position at which the bit line BL crosses a pair of adjacent word lines WL and WL and between the pair of word lines WL and WL.

As illustrated in FIG. 22, the MgO(001) layers 20 are provided on the Si(001) substrate 10 at predetermined intervals in the x-direction, and extend in the y-direction.

The word lines WL are provided on the MgO(001) layers 20. Each of the word lines WL has the same structure as the wire 30 in the first embodiment. In other words, a specific crystal orientation (a <110> crystal orientation) is substantially parallel to the y-direction in at least a part of the crystal grains in each of the word lines WL. The description of the same structure in the word lines WL as the first embodiment will be omitted. Note that the average interval between the adjacent word lines WL and WL can be wider than the mean free path of the free electrons in the Cu bulk crystal.

The MgO(001) layers 20 exist under the word lines WL and do not exist between the adjacent word lines WL and WL. In other words, an opening penetrating the MgO(001) layer 20 is provided between the adjacent word lines WL and WL.

The source layer S1 in the field effect transistor T1 is an n+ type semiconductor layer, and is provided on the Si(001) substrate 10 in the opening penetrating the MgO(001) layer 20.

The channel layer C1 is a semiconductor layer and is provided at the position that is on the source layer S1 and faces the pair of word lines WL and WL.

The second insulating layer 90 is provided between the channel layer C1 and the pair of word lines WL and WL to function as a gate insulating film of the field effect transistor T1.

The drain layer D1 is an n+ type semiconductor layer, and is provided on the channel layer C1.

The source layer S1, the channel layer C1, and the drain layer D1 are made, for example, of single crystal silicon, polysilicon, or amorphous silicon.

The pair of word lines WL and WL functions as a gate electrode of the field effect transistor T1. The field effect transistor T1 is a vertical double-gate n-Si transistor.

The variable resistive layer 100 is provided above the drain layer D1 and is electrically connected to the drain layer D1. The variable resistive layer 100 varies the resistance value depending on at least one of the applied voltage and current.

As described above, the memory cell MC is supported with the Si(001) substrate 10. Furthermore, the source layer S1, the channel layer C1, the drain layer D1, and the variable resistive layer 100 are layered in the z-direction (a vertical direction). The second insulating layer 90 surrounds the periphery of the layered source layer S1, channel layer C1, drain layer D1, and variable resistive layer 100 to insulate the layers from the adjacent memory cells MC in the y-direction.

The bit line BL is provided above the word lines WL and above the variable resistive layer 100 and is electrically connected to the variable resistive layer 100 through the bit line contact BC.

Insulating layers 91 are provided between the bit line BL and the word lines WL. The insulating layer 91 can be formed integrally with the second insulating layer 90.

The source line SL is an n+ type conductive layer provided in the Si(001) substrate 10. The source line SL is electrically connected to the source layer S1 and extends in the x-direction while overlapping with the bit line BL.

An MgO(001) layer 21 extending in the x-direction is provided between the adjacent source lines SL and SL in the y-direction. The MgO(001) layer 21 insulates the source lines SL and SL. The MgO(001) layer 21 is embedded in a groove formed in the Si(001) substrate 10. The surface of the MgO(001) layer 21 is at the same level as the surface of the Si(001) substrate 10. The MgO(001) layer 21 can be grown in the same process as the MgO(001) layer 20.

The semiconductor storage device having the structure described above controls the current flowing in the field effect transistor T1 by applying the voltage in the bit line BL, the word lines WL, and the source lines SL in order to read, write, or delete the data in the memory cell MC.

The present embodiment suppresses the size effect of electrical resistivity of the word line WL, and thus can lower the wire resistance than the conventional word line having the same area of the cross-sectional surface because the wire 30 in the first embodiment is used as the word lines WL. This can suppress the wire delay of the word line WL.

Corresponding to an amount of which the resistance of the word line WL is reduced, the wire width of the word line WL can be reduced. Therefore, the rate of integration of the memory cells MC can be improved.

### Tenth Embodiment

The tenth Embodiment relates to a resistance change type semiconductor storage device having a different structure from the ninth embodiment.

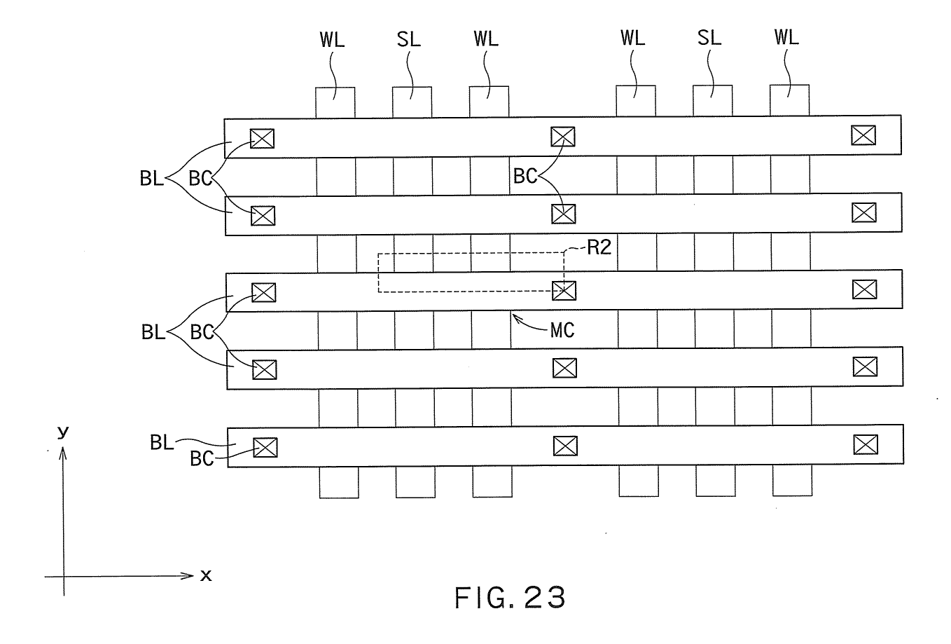

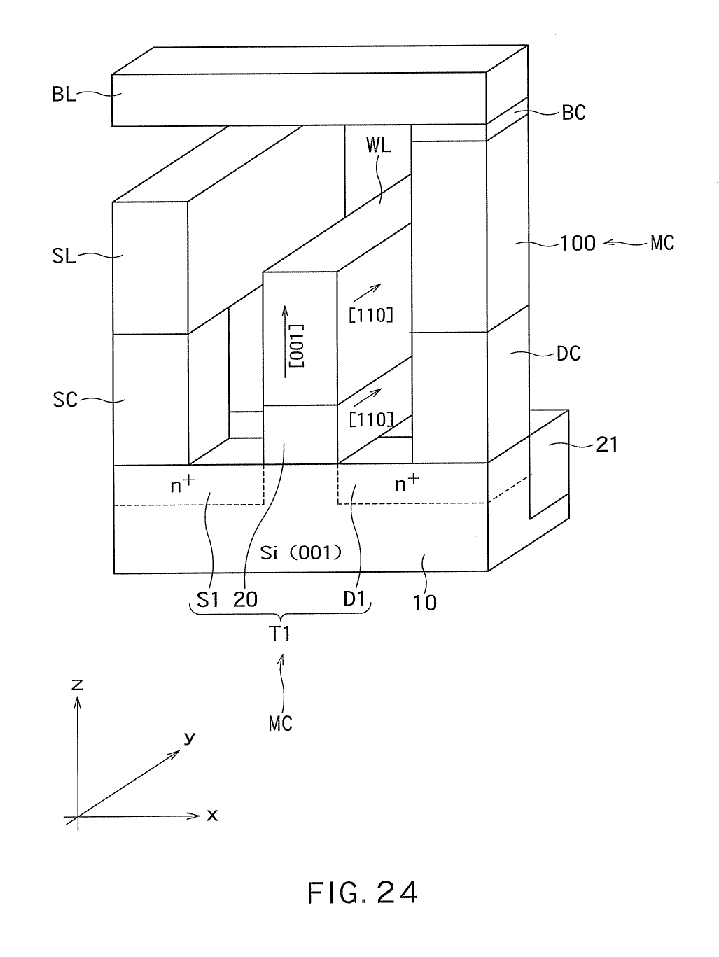

FIG. 23 is a schematic plan view of the structure of a semiconductor storage device according to the tenth Embodiment. FIG. 24 is a perspective view of a region R2 in FIG. 23. The region R2 corresponds to a memory cell MC.

As illustrated in FIGS. 23 and 24, the semiconductor storage device includes an Si(001) substrate (semiconductor substrate) 10, an MgO(001) layer (first insulating layer) 20, a plurality of word lines WL, a plurality of bit lines BL, a plurality of source lines SL, and a plurality of memory cells MC. The memory cell MC is a resistance change type memory cell, similar to the ninth embodiment. The memory cell MC includes a horizontal field effect transistor T1 functioning as a select transistor, and a variable resistive layer 100. The field effect transistor T1 includes a source layer S1, and a drain layer D1.

As illustrated in FIG. 23, the bit lines BL extend in the x-direction (a second direction, or a bit line direction) at predetermined intervals in the y-direction (a first direction, or a word line direction). The x-direction is substantially perpendicular to the y-direction. The word lines WL extend in the y-direction at predetermined intervals in the x direction. The word lines WL cross the bit lines BL.

The source line SL extends in the y-direction between a pair of adjacent word lines WL and WL. A source line SL is not provided between a pair of word lines WL and WL that is adjacent to the pair of word lines WL and WL between which the source line SL is provided.

The memory cell MC is provided at the position at which the bit line BL crosses the source line SL and the word line WL.

As illustrated in FIG. 24, the MgO(001) layers 20 are provided on the Si(001) substrate 10 at predetermined intervals in the x-direction, and extend in the y-direction.

The word lines WL are provided on the MgO(001) layers 20. The detailed description of each of the word lines WL will be omitted because the word lines WL have the same structure as the word lines WL in the ninth embodiment.

The MgO(001) layers 20 exist under the word lines WL and do not exist between the adjacent word lines WL and WL.

The field effect transistor T1 includes a pair of the source layer S1 and drain layer D1 provided in the semiconductor substrate 10, so as to be located at both sides of the word line WL. The source layer S1 and drain layer D1 each are an n+ type semiconductor layer. The MgO(001) layer 20 functions as a gate insulating film of the field effect transistor T1. The word line WL functions as a gate electrode of the field effect transistor T1.

The variable resistive layer 100 is provided above the drain layer D1 and is electrically connected to the drain layer D1 through a drain contact DC.

As described above, the memory cell MC is supported with the Si(001) substrate 10.

The MgO(001) layer 21 extending in the x-direction is provided between the source layer S1 and S1, between channels, and between the drain layers D1 and D1, namely, between the adjacent field effect transistors T1 and T1 in the y-direction. The MgO(001) layer 21 insulates the field effect transistors from each other. The MgO(001) layer 21 is embedded in a groove formed in the Si(001) substrate 10. The surface of the MgO(001) layer 21 is at the same level as the surface of the Si(001) substrate 10.

The source line SL is provided above the source layer S1 and is electrically connected to the source layer S1 through a source contact SC.

The bit line BL is provided above the source lines SL and the word lines WL and above a variable resistive layer and is electrically connected to the variable resistive layer 100 through the bit line contact BC.

An insulating layer such as a silicon oxide film is provided between the source line SL and the bit line BL, between the source line SL and the word line WL, and between the word line WL and the bit line BL, and the like.

The two memory cells MC and MC that are adjacent to each other in the x-direction and holding a source line SL therebetween share the source layer S1, the source line contact SC, and the source line SL.

The semiconductor storage device operates in the same manner as the ninth embodiment.

The present embodiment can provide the same effect as the ninth embodiment. In addition, the MgO(001) layer 20 that is a high-k film is used as a gate insulating film in the field effect transistor T1. Therefore, there can be reduced the leakage current to the word line WL, that is a gate electrode, more than that in the case in which SiO₂ is used as the gate insulating film.

Note that one of the wires in the second embodiment to the seventh embodiment can be used in the eighth to tenth embodiments instead of the Cu{100} wire.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a plurality of wires provided on an insulating layer,
wherein each of the wires comprises one or more metal crystal grains,
an average width of each of the wires and an average interval between the wires adjacent to each other are nearly equal to or less than a mean free path of free electrons in a bulk crystal of the metal, and
a specific crystal orientation in which size effect of electrical resistivity weakens due to anisotropy of Fermi velocity in the metal is substantially parallel to a current direction in at least a part of the crystal grains in each of the wires.

2. The semiconductor device according to claim 1, wherein, in each of the wires, an average size of the crystal grains in the current direction is larger than the mean free path of the free electrons.

3. The semiconductor device according to claim 1, wherein a crystal face on an upper surface of the insulating layer is substantially equivalent to crystal faces on upper surfaces of at least a part of the crystal grains in each of the wires.

4. The semiconductor device according to claim 1, wherein at least a part of the crystal grains in each of the wires is one of a Cu{100} crystal grain having an fcc structure, an Ag{100} crystal grain having an fcc structure, and an Au{100} crystal grain having an fcc structure,
a cross-sectional surface of each of the wires has an aspect ratio of four or less, and
the specific crystal orientation is a <110> crystal orientation.

5. The semiconductor device according to claim 4, wherein each of the wires is made of the single crystal grain.

6. The semiconductor device according to claim 1, wherein at least a part of the crystal grains in each of the wires is one of a Cu{110} crystal grain having an fcc structure, an Ag{110} crystal grain having an fcc structure, and an Au{110} crystal grain having an fcc structure, and
the specific crystal orientation is a <110> crystal orientation.

7. The semiconductor device according to claim 6, wherein each of the wires is made of the single crystal grain.

8. The semiconductor device according to claim 1, wherein at least a part of the crystal grains in each of the wires is an Al{100} crystal grain having an fcc structure,
a cross-sectional surface of each of the wires has an aspect ratio of two or more, and
the specific crystal orientation is a <110> crystal orientation.

9. The semiconductor device according to claim 8, wherein each of the wires is made of the single crystal grain.

10. The semiconductor device according to claim 1, wherein at least a part of the crystal grains in each of the wires is an Al{110} crystal grain having an fcc structure,
a cross-sectional surface of each of the wires has an aspect ratio of four or less, and
the specific crystal orientation is a <111> crystal orientation.

11. The semiconductor device according to claim 10, wherein each of the wires is made of the single crystal grain.

12. The semiconductor device according to claim 1, wherein at least a part of the crystal grains in each of the wires is an Mo{110} crystal grain having a bcc structure,
a cross-sectional surface of each of the wires has an aspect ratio of four or less, and
the specific crystal orientation is a <111> crystal orientation.

13. The semiconductor device according to claim 12, wherein each of the wires is made of the single crystal grain.

14. The semiconductor device according to claim 1, wherein at least a part of the crystal grains in each of the wires is an Mo{100} crystal grain having a bcc structure,
a cross-sectional surface of each of the wires has an aspect ratio of two or more, and
the specific crystal orientation is a <110> crystal orientation.

15. The semiconductor device according to claim 14, wherein each of the wires is made of the single crystal grain.

16. A semiconductor storage device comprising:
a semiconductor substrate;
a first insulating layer provided on the semiconductor substrate;
a plurality of wires provided on the first insulating layer and extending in a first direction; and
a memory cell supported with the semiconductor substrate, wherein each of the wires comprises one or more metal crystal grains,
an average width of each of the wires is nearly equal to or less than a mean free path of free electrons in a bulk crystal of the metal,
a specific crystal orientation in which size effect of electrical resistivity weakens due to anisotropy of Fermi velocity in the metal is substantially parallel to the first direction in at least a part of the crystal grains in each of the wires, and
the wires are bit lines or word lines.

17. The semiconductor storage device according to claim 16, wherein the wires are bit lines, and
the semiconductor storage device further comprising:
a second insulating layer covering the bit lines; and
a NAND string comprising a plurality of the memory cells provided on the second insulating layer and arranged in the first direction, and an end of the NAND string being electrically connected to the bit line.

18. The semiconductor storage device according to claim 16, wherein the wires are word lines,
the memory cell is provided between a pair of the word lines adjacent to each other,
the memory cell comprises:
a vertical field effect transistor, the pair of word lines functioning as a gate electrode of the field effect transistor, the field effect transistor including
a source layer provided on the semiconductor substrate in an opening penetrating the first insulating layer,
a channel layer provided at a position on the source layer and facing the pair of word lines,
a second insulating layer provided between the channel layer and the pair of word lines, and
a drain layer provided on the channel layer; and
a variable resistive layer provided above the drain layer, electrically connected to the drain layer, and varying a resistance value, and
the semiconductor storage device further comprising:
a bit line provided above the variable resistive layer, electrically connected to the variable resistive layer, and crossing the word lines;
a source line provided in the semiconductor substrate, electrically connected to the source layer, extending while overlapping with the bit line, and being conductive layer.

19. The semiconductor storage device according to claim 16, wherein the wires are word lines, and
the memory cell comprises:
a field effect transistor comprising a pair of source layer and drain layer provided in the semiconductor substrate, so as to be located at both sides of the word line, the word line functioning as a gate electrode of the field effect transistor; and
a variable resistive layer provided above the drain layer, electrically connected to the drain layer, and varying a resistance value, and
the semiconductor storage device further comprising:
a source line provided above the source layer, electrically connected to the source layer, and extending in the first direction; and
a bit line provided above the variable resistive layer, electrically connected to the variable resistive layer, and crossing the source line and the word lines.

20. A method for manufacturing a semiconductor device, the method comprising:
forming an insulating layer on a semiconductor substrate with epitaxial growth;
forming a metal layer on the insulating layer with epitaxial growth;
specifying a specific crystal orientation in which size effect of electrical resistivity weakens due to anisotropy of Fermi velocity in the metal layer according to a mark showing a crystal orientation of the semiconductor substrate and a relationship between crystal orientations of the insulating layer and the metal layer; and
forming a plurality of wires by processing the metal layer such that an average width of each of the wires and an average interval between the wires adjacent to each other are nearly equal to or less than a mean free path of free electrons in a metal bulk crystal of the metal layer, and such that the specific crystal orientation is substantially parallel to a current direction in at least a part of the crystal grains in each of the wires.
